(19) United States
(12) Patent Application Publication
(10) Pub. No.: US 2011/0104454 A1
(43) Pub. Date: May 5, 2011

(54) COMPOSITION FOR FORMING LAYER TO BE PLATED, METHOD OF PRODUCING METAL PATTERN MATERIAL, AND METAL PATTERN MATERIAL

(75) Inventors: Takatsugu KAWANO, Kanagawa (JP); Takeyoshi KANO, Kanagawa (JP)

(73) Assignee: FUJIFILM CORPORATION, Tokyo (JP)

(21) Appl. No.: 12/910,884

(22) Filed: Oct. 25, 2010

(30) Foreign Application Priority Data
Oct. 29, 2009 (JP) 2009-249382

(51) Int. Cl. B32B 3/00; G03F 7/004; G03F 7/20

(52) U.S. Cl. 428/195.1; 430/270.1; 430/286.1; 430/283.1; 430/324

(57) ABSTRACT

The present invention provide a composition for forming a layer to be plated, including a solution in which from 1% by mass to 20% by mass of a polymer having a functional group that forms an interaction with a plating catalyst or a precursor thereof and a radical polymerizable group, and a water-insoluble photopolymerization initiator are dissolved in a mixed solvent comprising from 20% by mass to 99% by mass of a water-soluble flammable liquid and water; a method of producing a metal pattern material using the composition for forming a layer to be plated; and a metal pattern material produced by the method.

### CROSS-REFERENCE TO RELATED APPLICATION

This application claims priority under 35 USC 119 from Japanese Patent Application No. 2009-249382 filed Oct. 29, 2009, the disclosure of which is incorporated by reference herein.

### BACKGROUND OF THE INVENTION

1. Field of the Invention

The present invention relates to a composition for forming a layer to be plated, a method of producing a metal pattern material, and a metal pattern material.

2. Description of the Related Art

Conventionally, a metal wiring board having a patterned metal wiring (a wiring formed from a metal pattern material) formed on an insulating substrate has been widely used in electronic devices or semiconductor devices.

Such a metal pattern material is produced typically by a subtractive method. This method includes forming, on a metal film formed on a substrate, a photosensitive layer that is sensitized by irradiating with active light, exposing the photosensitive layer with light in an image-wise manner, developing the same to form a resist image, forming a metal pattern by etching the metal film, and then peeling off the resist image.

In a case in which a metal pattern is obtained by the subtractive method, adhesiveness between a substrate and a metal film is achieved by an anchoring effect that is obtained by roughening a surface of the substrate. On the other hand, there is a problem in that, when a metal pattern material is used for a metal wiring, degradation in high-frequency characteristics may occur due to a roughness at the interfacial portion of the obtained metal pattern and the substrate. Further, there is a problem in that since the surface of the substrate needs to be treated with a strong acid such as chromium acid for roughening, a complicated process is required in order to obtain a metal pattern that exhibits excellent adhesiveness between the metal film and the substrate.

In order to solve the above problem, Advanced Materials 2000, 12, No. 20, October 16, pp. 1481-1494 proposes a method of improving the adhesiveness between the substrate and the metal film without performing surface roughening, the method including subjecting the substrate surface to a plasma treatment and introducing a polymerization initiating group thereto, and then producing a surface graft polymer having a polar group on the surface of the substrate by polymerizing a monomer from the polymerization initiating group.

Further, International Publication WO 08/050715 discloses a method of obtaining a metal pattern (plating film) that exhibits excellent adhesiveness with respect to a substrate, the method including forming a polymer layer on the substrate by producing a graft polymer that bonds to the substrate, performing plating with respect to the polymer layer, and then etching the obtained metal film.

However, the above method utilizes, as a compound that forms a graft polymer, a polymer having a polymerizable group and a non-dissociative functional group that interacts with a plating catalyst or a precursor thereof. This polymer has low affinity to an aqueous solution. As a result, in the case of developing with an aqueous solution a portion of the polymer layer formed on the substrate, highly alkali water needs to be used and it takes a long time for the development process.

### SUMMARY OF THE INVENTION

The present invention has been made in view of the aforementioned circumstances. A first aspect of the invention provides a composition for forming a layer to be plated, the composition including a solution in which from 1% by mass to 20% by mass of a polymer having a functional group that forms an interaction with a plating catalyst or a precursor thereof and a radical polymerizable group, and a water-insoluble photopolymerization initiator are dissolved in a mixed solvent including from 20% by mass to 99% by mass of a water-soluble flammable liquid and water.

### DETAILED DESCRIPTION OF THE INVENTION

Herein, the water-insoluble photopolymerization initiator is preferably contained in the range of from 1% by mass to 20% by mass with respect to the polymer. Further, the water-soluble flammable liquid is preferably an alcohol-based solvent.

In the invention, a functional group forming an interaction with a plating catalyst or a precursor thereof in the polymer having the functional group forming an interaction with the plating catalyst or the precursor thereof and a radical polymerizable group is preferably a non-dissociative functional group or an ionic polar group that forms an interaction with the plating catalyst or the precursor thereof. Further, the polymer having the functional group that forms interaction with the plating catalyst or the precursor thereof and the radical polymerizable group is preferably a copolymer which contains a unit represented by the following Formula (A) and a unit represented by the following Formula (B).

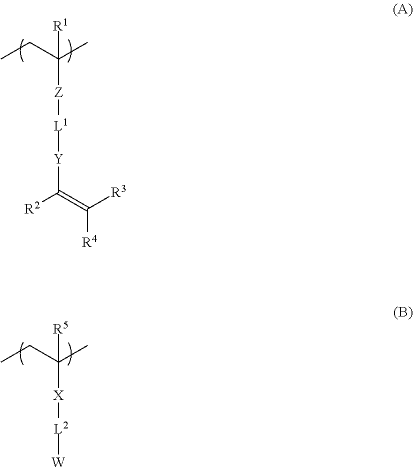

In Formula (A) and Formula (B), R¹ to R⁵ each independently represent a hydrogen atom, or a substituted or unsubstituted alkyl group; X, Y, and Z each independently represent a single bond, a substituted or unsubstituted divalent organic group, an ester group, an amide group, or an ether group; L¹ and L² each independently represent a single bond, or a substituted or unsubstituted divalent organic group; and W represents an ionic polar group that forms an interaction with a plating catalyst or a precursor thereof.

In the unit represented by Formula (B), W preferably represents a carboxylic group. An embodiment in which W represents a carboxylic group and a four to eight membered ring structure is included in a connecting portion to X of L² is preferred. Furthermore, an embodiment in which W is a carboxylic group and a chain length of L³ is from 6 atoms to 18 atoms is also preferred.

Further, an embodiment in which, in the unit represented by Formula (B), W is a carboxylic group and both X and L² are each a single bond is preferred.

Further, the polymer having an ionic polar group that forms an interaction with a plating catalyst or a precursor thereof and a radical polymerizable group further may contain a unit represented by the following Formula (C) as a copolymerization component.

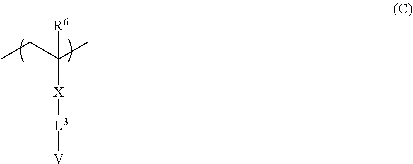

In Formula (C), R⁶ represents a hydrogen atom, or a substituted or unsubstituted alkyl group; X represents a single bond, a substituted or unsubstituted divalent organic group, an ester group, an amide group, or an ether group; L³ represents a single bond, or a substituted or unsubstituted divalent organic group; and V represents a non-dissociative functional group that forms an interaction with a plating catalyst or a precursor thereof.

In the unit represented by Formula (C), V represents preferably a cyano group or an ether group.

A method of producing the metal pattern material of the invention has steps of (1) coating a composition of the invention for forming a layer to be plated on or above a substrate to form a coated film for forming a layer to be plated, then applying energy to the coated film for forming a layer to be plated, to cure the coated film in an area to which the energy has been applied, (2) developing the uncured area of the coated film on or above the substrate with an aqueous solution, to form a patterned layer to be plated, (3) applying a plating catalyst or a precursor thereof to the patterned layer to be plated, and (4) plating the plating catalyst or the precursor thereof.

Herein, energy application is preferably carried out by exposure to light having a wavelength of from 250 nm to 400 nm, and more preferably from 280 nm to 370 nm.

The metal pattern material of the invention is a product obtained by the above-described method of producing the metal pattern material of the invention.

### Effect of Invention

According to the present invention, it is possible to provide a composition for forming a layer to be plated, which composition can be cured at high sensitivity by application of energy and developed with an aqueous solution to form a pattern of the layer to be plated with a high resolution and having an excellent adsorption property with respect to a plating catalyst or a precursor thereof. Further, the present invention makes it possible to provide a method of producing a metal pattern material in which a metal pattern having excellent adhesiveness with respect to a substrate can be readily formed by development with an aqueous solution, and further to provide a metal pattern material obtained by the method.

Hereinafter, details of the present invention are described.

The composition for forming a layer to be plated according to the invention contains a polymer that has a functional group that interacts with a plating catalyst or a precursor thereof, and a radical polymerizable group. In the following description, the polymer having a functional group that interacts with a plating catalyst or a precursor thereof and a radical polymerizable group that is used in the invention is sometimes referred to as “a specific polymer”.

Specific Polymer

The specific polymer according to the invention preferably has, in the molecule thereof, an ionic polar group acting as a functional group that interacts with a plating catalyst or a precursor thereof (hereinafter, sometimes referred to as “an ionic interactive group”), and a radical polymerizable group.

An interactive group in the specific polymer preferably includes an ionic polar group, and is not particularly limited, as long as the group is capable of forming a multidentate coordination with a metal. Further, the interactive group may include, in addition to the ionic polar group, a non-dissociative functional group (i.e., a functional group that does not generate protons by dissociation) such as a nitrogen-containing functional group, a sulfur-containing functional group, or an oxygen-containing functional group.

As described above, examples of the optimal embodiment of an interactive group in the specific polymer includes an ionic polar (ionic interactive) group. The ionic polar group has a function of absorbing a plating catalyst or a precursor thereof, and further a function of imparting an ability to be developed with aqueous solution to the specific polymer. Examples of the ionic interactive group specifically include a carboxylic group, a sulfonic group, a phosphoric group, and a boronic group. Among them, from the viewpoints of suitable acidity (without decomposing other functional groups), a carboxylic group is preferred. From the viewpoints of compatibility of a necessary low water absorbability and an interaction as an electric wiring, in particular, a carboxylic group directly bonded to an alicyclic structure (alicyclic carboxylic group) and a carboxylic group apart from the main chain of polymer (long chain carboxylic group) are preferred.

As described below, the ionic interactive group may be introduced into a specific polymer by adding to and substituting for a part of the specific polymer, or may be introduced into the specific polymer by copolymerizing a monomer (unit) with a pendant ionic interactive group.

The ionic interactive group in the invention is further preferably a carboxylic group.

The ionic interactive group may be introduced in a specific polymer by copolymerizing a monomer with a pendant ionic interactive group, or may be introduced in the specific polymer by adding to and substituting for a part of the previously synthesized polymer (for example, a polymer having a radical polymerizable group).

The specific polymer according to the invention may further contain a non-ionic interactive group capable of forming a polydentate coordination with a metal, in other words, a non-dissociative functional group such as a nitrogen-containing functional group, a sulfur-containing functional group, or an oxygen-containing group.

The non-dissociative functional group is preferably a functional group capable of coordinating with a metal ion, a nitrogen-containing functional group, a sulfur-containing functional group, an oxygen-containing functional group, or the like. Specific examples thereof include nitrogen-containing functional groups such as an imide group, a pyridine group, a tertiary amino group, an ammonium group, a pyrrolidone group, an amidino group, a triazine group, a triazole group, a benzotriazol group, a benzoimidazole group, a quinoline group, a pyrimidine group, a pyrazine group, a quinazoline group, a quinoxaline group, a purine group, a triazine group, a piperidine group, a piperazine group, a pyrrolidine group, a pyrazole group, an aniline group, a group having an alkylamine group structure, a group having an isocyanuric structure, a nitro group, a nitroso group, an azo group, a diazo group, an azide group, a cyano group and a cyanate (R—O—CN) group; oxygen-containing functional groups such as a hydroxyl group, a carbonate group, an ether group, a carbonyl group, an ester group, a group having an N-oxide structure, a group having an S-oxide structure and a group having an N-hydroxy structure; sulfur-containing functional groups such as a thiophene group, a thiol group, a thiocyanuric acid group, a benzothiazole group, a mercaptotriazine group, a thioether group, a thioxy group, a sulfoxide group, a sulfonic group, a sulfite group, a group having a sulfoximine structure, a group having a sulfoxonium salt structure, and a group having a sulfonic acid ester structure; phosphorus-containing functional groups such as a phosphate group, a phosphoramide group and a phosphine group; groups containing a halogen atom such as chlorine or bromine; and groups containing an unsaturated ethylenic bond. An imidazole group, a urea group or a thiourea group are also applicable if the group acts as a non-dissociative functional group with respect to an adjacent atom or atomic group. Further, a functional group derived from a compound capable of forming a clathrate such as cyclodextrin or crown ether may be used.

Among them, an ether group (more specifically, a group having a structure represented by —O—(CH₂)n-O—, where n is an integer of from 1 to 5) or a cyano group is particularly preferred from the viewpoint of high polarity and high adsorption capacity to a plating catalyst or the like, and a cyano group is most preferred.

In general, as a result of introducing the above-described ionic polar group thereto, the higher the polarity of the specific polymer is, the higher the water absorption rate tends to be. However, since the cyano groups interact with each other so as to cancel the polarity thereof in the layer to be plated, the layer becomes dense and the polarity of the layer as a whole decreases as a result of further introducing such functional group. Therefore, the water absorbancy of the layer can be reduced in spite of its high polarity. Further, when the catalyst is adsorbed to the layer to be plated using a good solvent for the layer, the cyano groups are solvated to cancel the interaction between them, which enables the cyano groups to interact with the plating catalyst. For the above reasons, the layer to be plated that contains a cyano group is preferable in terms of balancing competing properties, i.e., low water absorbency and good interactive property with a plating catalyst.

The radical polymerizable group in the specific polymer is not particularly limited as long as it is a functional group capable of polymerization directly by applying energy, or by means of a radical that is generated from a co-existing radical generating agent. Specific examples thereof include an acryloyl group, a methacryloyl group, an acrylamide group, a methacrylamide group, an allyl group, a vinyl group, and a styryl group. Among these, an acryloyl group, a methacryloyl group, an acrylamide group and a methacrylamide group are preferred from the viewpoint of radical polymerization reactivity and synthesis versatility.

The radical polymerizable group may be introduced in a specific polymer by copolymerizing a monomer with a pendant radical polymerizable group, or may be introduced in the specific polymer by adding to and substituting for a part of the previously synthesized polymer (for example, a polymer having an ionic interactive group).

The specific polymer used in the invention is preferably a copolymer containing a unit represented by the following Formula (A) and a unit represented by the following Formula (B).

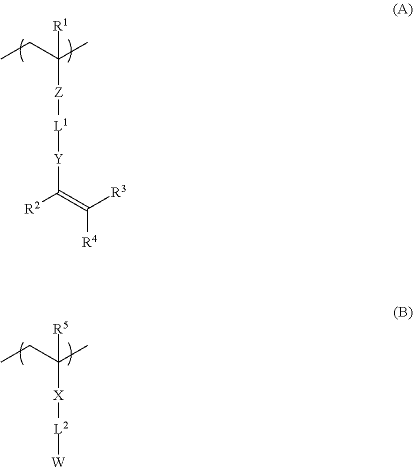

In Formulae (A) and (B), R¹ to R⁵ each independently represent a hydrogen atom or an alkyl group that may be substituted or unsubstituted; X, Y, and Z each independently represent a single bond, a divalent organic group that may be substituted or unsubstituted, an ester group, an amide group or an ether group; L¹ and L² each independently represent a single bond or a divalent organic group that may be substituted or unsubstituted; and W represents an ionic polar group that interacts with a plating catalyst or a precursor thereof.

When R¹ to R⁵ are an alkyl group that may be substituted or unsubstituted, examples of the alkyl group that is not substituted include a methyl group, an ethyl group, a propyl group and a butyl group. Examples of the alkyl group that is substituted include a methyl group, an ethyl group, a propyl group and a butyl group that are substituted with a methoxy group, a hydroxyl group, a chlorine atom, a bromine atom, a fluorine atom or the like.

R¹ is preferably a hydrogen atom, a methyl group, or a methyl group that is substituted with a hydroxyl group or a bromine atom.

R² is preferably a hydrogen atom, a methyl group, or a methyl group that is substituted with a hydroxyl group or a bromine atom.

R³ is preferably a hydrogen atom.

R⁴ is preferably a hydrogen atom.

R⁵ is preferably a hydrogen atom, a methyl group, or a methyl group that is substituted with a hydroxyl group or a bromine atom.

R⁶ is preferably a hydrogen atom, a methyl group, or a methyl group that is substituted with a hydroxyl group or a bromine atom.

Further, in view of the flexibility of the specific polymer, it is preferred that both of R¹ and R⁵ are each a hydrogen atom.

When X, Y and Z are each a divalent organic group that may be substituted or unsubstituted, examples thereof include an aliphatic hydrocarbon group that may be substituted or unsubstituted, and an aromatic hydrocarbon group that may be substituted or unsubstituted.

X, Y and Z are preferably a single bond, an ester group, an amide group or an ether group, more preferably a single bond, an ester group or an amide group, and yet more preferably a single bond or an ester group.

Further, in one preferred embodiment, each of L¹ and L² is a linear, branched or cyclic alkylene group, an aromatic group, or a combination of these groups. The combination of an alkylene group and an aromatic group may include an ether group, an ester group, an amide group, a urethane group or a urea group in between. In particular, L¹ and L² preferably include the total number of carbon atoms of 1 to 15, and are preferably not substituted. The total number of carbon atoms here refers to the total number of carbon atoms included in a substituted or unsubstituted divalent organic group that is represented by, for example, L¹. The same applies to L².

Specific examples of the divalent organic group include a methylene group, an ethylene group, a propylene group, a butylene group, a phenylene group, these groups substituted with a methoxy group, a hydroxyl group, a chlorine atom, a bromine atom, a fluorine atom or the like, and a combination of these groups.

In particular, in the unit represented by Formula (B), from the viewpoints of a suitable acidity (without decomposing other functional groups) and hydrophilicity in aqueous alkali solution whereas easy change to hydrophobicity due to a cyclic structure when water is dried, an embodiment is preferred in which W represents a carboxylic group and a four-to eight-membered ring structure is included in a connecting portion to W of L². Herein, the four-to eight-membered ring structure includes a cyclobutyl group, a cyclopentyl group, a cyclohexyl group, a cycloheptyl group, a cyclooctyl group, and a phenyl group. Among them, a cyclohexyl group and a phenyl group are preferred. In order words, in this embodiment, a terminal of the unit represented by Formula (B) is an alicyclic carboxylic group.

Further, in the unit represented by Formula (B), from the viewpoints of a suitable acidity (without decomposing other functional groups) and hydrophilicity in aqueous alkali solution whereas easy change to hydrophobicity due to a long chain alkyl group structure when water is dried, an embodiment is preferred in which V represents a carboxylic group and a chain length of L² is preferably from 6 atoms to 18 atoms. Herein, a chain length of L² represents a distance between X and W in Formula (B) and X and W are preferably separated in a range of from 6 atoms to 18 atoms. A chain length of L² is more preferably from 6 atoms to 14 atoms, and further preferably from 6 atoms to 12 atoms.

Further, in the unit represented by Formula (B), an embodiment is also preferable in which W is a carboxylic group and X and L² are a single bond.

In this embodiment, immediately after forming a metal pattern, adhesiveness of the metal pattern to a substrate can be increased, and further, resistance to water of a layer to be plated can be increased.

The specific polymer in the invention may further contain the unit represented by the following Formula (C).

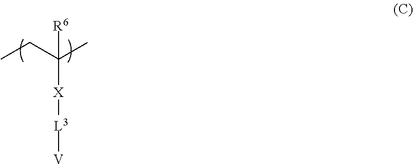

In the unit represented by Formula (C), V represents a non-dissociative functional group that forms interaction with a plating catalyst or a precursor thereof. Examples of the non-dissociative functional group include the group described above. Among them, a cyano group or an ether group is preferable as V from the viewpoints of high polarity and high absorption ability to a plating catalyst.

In Formula (C), R⁶ represents a hydrogen atom, or a substituted or unsubstituted alkyl group; X represents a single bond, a substituted or unsubstituted divalent organic group, an ester group, an amide group, or an ether group; and L³ represents a single bond, or a substituted or unsubstituted divalent organic group. Herein, R⁶ is preferably a hydrogen atom, a methyl group, or a methyl group substituted with a hydroxyl group or a bromine atom.

In a case in which X represents a substituted or unsubstituted divalent organic group, examples of the divalent organic group include a substituted or unsubstituted aliphatic hydrocarbon group, a substituted or unsubstituted aromatic hydrocarbon group.

X is preferably a single bond, an ester group, an amide group, an ether group, more preferably a single bond, an ester group, or an amide group, and most preferably a single bond or an ester group.

L³ represents a single bond, or a substituted or unsubstituted divalent organic group, and among these, the divalent organic group is preferred. An embodiment is preferable in which the substituted or unsubstituted divalent organic group represented by L³ represents a straight, branched, or cyclic alkylene group, an aromatic group, or a combination of these groups. Further in the case of constituting the combination, an ether group, an ester group, an amide group, a urethane group, or a urea group may lie between the alkylene group and aromatic group. Among them, L³ is preferably the divalent organic group having a total carbon number of from 1 to 15 and most preferably an unsubstituted divalent organic group. Herein, the total carbon number means a total number of carbon atoms contained in a substituted or unsubstituted divalent organic group represented by L³.

In a case in which the specific polymer is made by copolymerization of a unit represented by Formula (A) and a unit represented by Formula (B), the unit represented by Formula (A) is preferably contained in a proportion of from 5% by mol to 50% by mol, and more preferably from 5% by mol to 30% by mol, with respect to all of the copolymerization units, from the viewpoints of reactivity (curability, polymerizability) and suppression of gelation during synthesis.

The unit represented by Formula (B) is preferably contained in a proportion of from 20% by mol to 90% by mol, and more preferably from 50% by mol to 90% by mol, with respect to all of the copolymerization units, from the viewpoints of adsorbability of a plating catalyst or a precursor thereof, developability with an aqueous solution, and humidity resistant adhesiveness. In particular, a proportion of from 70% by mol to 90% by mol is preferred.

Specifically, for example, a polymer synthesized by a method described in Japanese Patent Application Laid-Open (JP-A) No. 2008-166435 can be used.

In a case in which the specific polymer is a copolymer containing a unit represented by Formula (C) in addition to the unit represented by Formula (A) and the unit represented by Formula (B), the unit represented by Formula (A) is preferably contained in a proportion of from 5% by mol to 50% by mol, and more preferably from 5% by mol to 30% by mol, with respect to all of the copolymerization units, from the viewpoints of reactivity (curability, polymerizability) and suppression of gelation during synthesis.

The unit represented by Formula (B) is preferably contained in the proportion of from 20% by mol to 70% by mol, and more preferably from 20% by mol to 60% by mol, with respect to all of the copolymerization units, from the viewpoints of developability with an aqueous solution and humidity resistant adhesiveness. In particular, the proportion of from 30% by mol to 50% by mol is preferred. In this range, a better balance between developability and humidity resistant adhesiveness can be achieved;

The unit represented by Formula (C) is preferably contained in the proportion of from 5% by mol to 80% by mol, and more preferably from 10% by mol to 70% by mol, with respect to all of the copolymerization units, from the viewpoints of adsorbability of a plating catalyst or a precursor thereof.

Further, the value of ionic polarity (an acid value in a case in which the ionic polar group is an acidic group such as a carboxyl group or a sulfonic group) of the unit represented by Formula (B) in the specific polymer is preferably from 1.5 mmol/g to 10.0 mmol/g, more preferably from 1.7 mmol/g to 5.0 mmol/g, yet more preferably from 1.9 mmol/g to 5.0 mmol/g, and most preferably from 2.5 mmol/g to 4.5 mmol/g. When the value of ionic polarity is within the above range, a balance between developability with an aqueous solution and suppression of reduction in adhesiveness over time under hot and humid conditions can be achieved.

The optimal number of the units and the value of ionic polarity may vary depending on a molecular weight of the unit having an ionic polarity. However, in this case, optimization of the value of ionic polarity so as to be within the above range is given priority.

The specific examples of the specific polymer used in the invention are shown below, but the invention is not limited thereto.

Further, the weight average molecular weight of these specific examples are all in the range of from 3, 000 to 150,000.

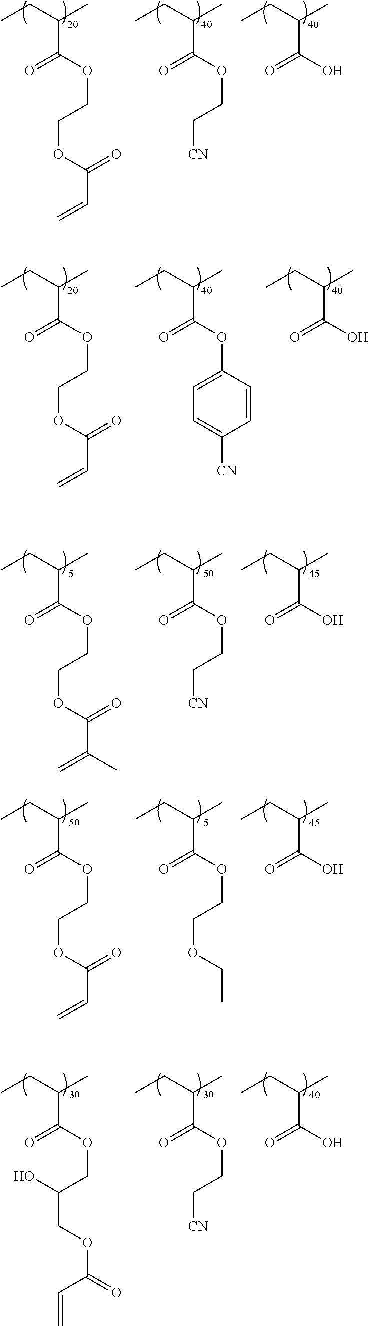

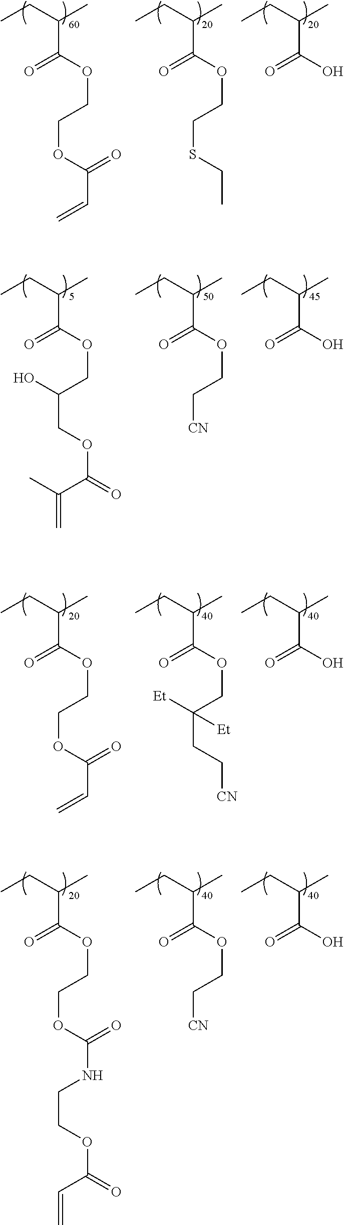

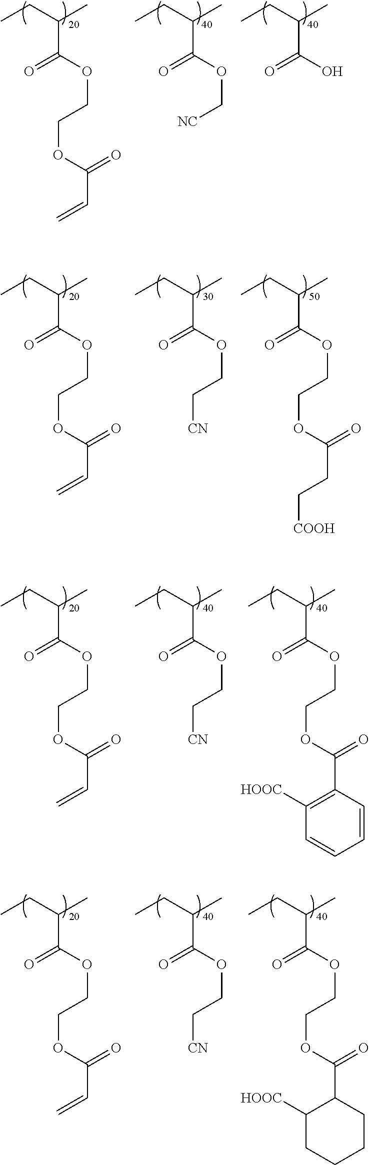

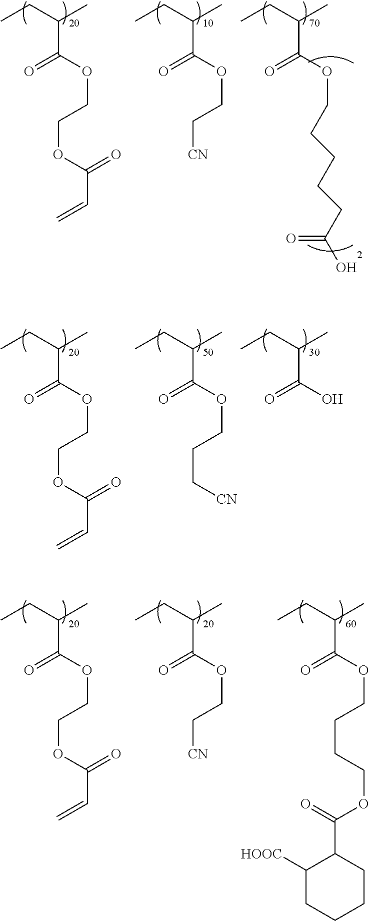

Synthesis Method of Specific Polymer

In the following, the synthesis method of a polymer including all of the units represented by formulae (A) to (C) among the specific polymer according to the invention is described.

The specific polymer including all of the units represented by formulae (A) to (C) according to the invention is not particularly limited as long as it has the aforementioned radical polymerizable group, ionic interactive group and non-dissociative interactive group. However, the specific polymer preferably has each of these groups in a side chain thereof. The specific polymer is preferably a copolymer that includes a unit having a non-dissociative interactive group, a unit having a radical polymerizable group, and a unit having an ionic interactive group, such as the aforementioned copolymer including the units represented by formulae (A) to (C).

The following is explanation of the specific polymer in the form of a copolymer that includes a unit having a non-dissociative interactive group, a unit having a radical polymerizable group, and a unit having an ionic interactive group, and synthesis methods thereof.

Examples of the synthesis method of the specific polymer in the form of a copolymer as described above include the following methods i), ii) and iii).

i) a method of copolymerizing a monomer having a non-dissociative interactive group, a monomer having a radical polymerizable group, and a monomer having an ionic interactive group.

ii) a method of copolymerizing a monomer having a non-dissociative interactive group, a monomer having a double bond precursor, and a monomer having an ionic interactive group, and then introducing a double bond into the copolymer by treating the copolymer with a base or the like.

iii) a method of synthesizing a polymer having a reactive group from a monomer having a non-dissociative interactive group and a monomer having an ionic interactive group, and then reacting the polymer with a monomer having a radical polymerizable group that can react with the reactive group in the polymer, thereby introducing a double bond (polymerizable group) into the polymer.

Among the above, the method ii) or iii) is preferred in view of synthesis suitability.

As mentioned above, the radical polymerizable group may be introduced into the specific polymer by copolymerizing a monomer having a pendant radical polymerizable group, or by adding a radical polymerizable group to a portion of the previously synthesized polymer (such as a polymer having an ionic interactive group and a non-dissociative interactive group), or alternatively by substituting a portion of the previously synthesized polymer (such as a polymer having an ionic polar group and an interactive group) with a radical polymerizable group. These methods are described in JP-A-2008-166435 as described above.

In synthesizing the specific polymer by any one of the method i), ii) or iii), a monomer of other kind may be copolymerized together with the above monomers, in order to reduce water absorption of the obtained specific polymer, or to improve hydrophobic property of the same. Examples of such a monomer include typical radical polymerizable monomers, such as diene monomers and acrylic monomers. Among these, alkyl acrylates having no substituent, such as tertiary butyl acrylate, 2-ethylhexyl acrylate, butyl acrylate, cyclohexyl acrylate and benzyl methacrylate are preferred.

The monomer having a non-dissociative interactive group used in the methods i), ii) and iii) is not particularly limited as long as it has a non-dissociative functional group as mentioned above, and specific examples thereof include the following. These monomers may be used alone or in combination of two or more.

Namely, examples of the monomer having a non-dissociative functional group include N-vinyl pyrolidone, N-vinyl imidazole, cyanoethyl acrylate, 1-methyl-cyanomethyl acrylate, 2-nitro-ethyl acrylate, 2-cyano-ethyl acrylamide, 1-methyl-cyanomethyl methacrylamide, 4-cyano-phenyl acrylate, N-cyanoethyl-N-ethyl-acrylamide, 3-cyano-propyl acrylate, 2-cyano-2-methyl-ethyl acrylate, 4-cyano-butyl acrylate, 5-cyano-pentyl acrylate, 6-cyano-hexyl acrylate, 1-cyano-methyl acrylate, 1-cyano-cyclohexyl acrylate, p-cyano-styrene, 4-cyano-2,2-diethyl-butyl methacrylate, and the compounds as shown below.

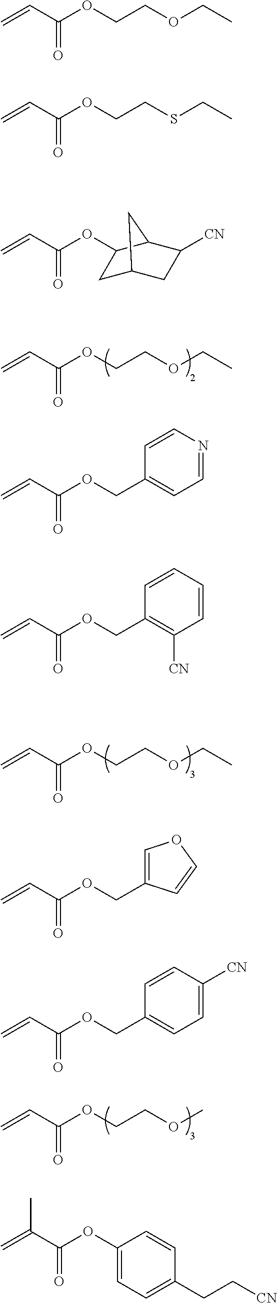

The monomer having an ionic interactive group used in the methods i), ii) and iii) is not particularly limited as long as it has an ionic interactive group as mentioned above, and examples thereof include a monomer having a carboxyl group, a sulfonic group, a phosphoric group or a boronic group. Specific examples thereof are described below. These monomers may be used alone or in combination of two or more.

Specific examples of the monomer having an ionic interactive group include acrylic acid, fumaric acid, methacrylic acid, 4-vinyl benzoate, and the compounds as shown below.

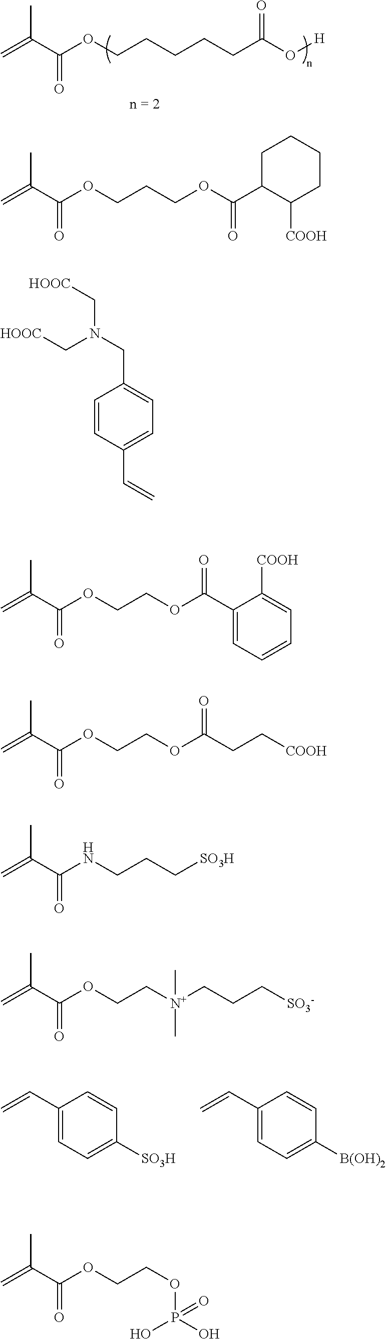

As a monomer including a carboxyl group, ARONIX M-5300, M-5400 and M-5600 (trade name, manufactured by TOAGOSEI CO., LTD.), ACRYLESTER PA and HH (trade name, manufactured by MITSUBISHI RAYON CO., LTD.), LIGHT-ACRYLATE series (trade name, manufactured by KYOEISHA CHEMICAL CO., LTD.) and NK ESTER SA and A-SA (trade name, manufactured by SHIN-NAKAMURA CHEMICAL CO. LTD.).

Examples of the monomer having a radical polymerizable group used in the method i) include allyl (meth)acrylate, compounds described in paragraph [0027] of JP-A No. 2008-166435 and the following compounds.

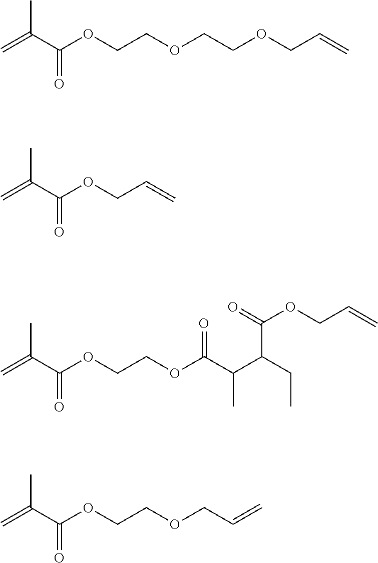

Examples of the monomer having a double bond precursor used in the synthesis method of the aforementioned ii) include the compound represented by the general formula described in paragraph [0027] of JP-A No. 2008-166435, specifically, the compound described in paragraph [0029] of JP-A No. 2008-166435 and, for example, the following compound.

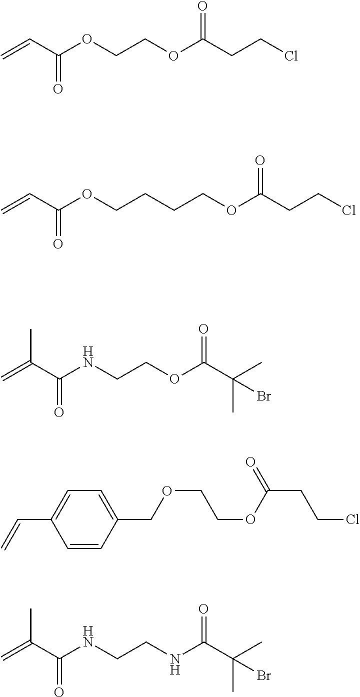

Further, in the synthesis method of the aforementioned ii), the method described in paragraphs [0032] to [0036] of the aforementioned publication may be used in conversion of a double bond precursor to a double bond.

The polymer used in the aforementioned method iii) can be synthesized by performing radical polymerization of a monomer having a non-dissociative interactive group, a monomer having an ionic interactive group and a monomer having a reactive group for introduction of a double bond. In this case, the ionic interactive group and the reactive group may be the same.

Example of the monomer having a reactive group for introduction of a double bond include monomers having, as a reactive group, a carboxyl group, a hydroxyl group, an epoxy group, or an isocyanate group.

Examples of the monomer having a carboxyl group include acrylic acid, methacrylic acid, itaconic acid, vinyl benzoate, ARONIX M-5300, M-5400 and M-5600 (trade name, manufactured by TOAGOSEI CO., LTD.), ACRYLESTER PA and HH (trade name, manufactured by MITSUBISHI RAYON CO., LTD.), LIGHT ACRYLATE HOA-HH (trace name, manufactured by KYOEISHA CHEMICAL CO., LTD.) and NK ESTER SA and A-SA (trade name, manufactured by SHIN-NAKAMURA CHEMICAL CO. LTD.).

Examples of the monomer having a hydroxyl group include 2-hydroxyethyl (meth)acrylate, 4-hydroxybutyl(meth)acrylate, 2-hydroxypropyl(meth)acrylate, 2-hydroxybutyl(meth)acrylate, 1-(meth)acryloyl-3-hydroxy adamantane, hydroxymethyl(meth)acrylamide, 2-(hydroxymethyl)(meth)acrylate, 2-(hydroxymethyl)-(meth)acrylate, a methyl ester of 2-(hydroxymethyl)(meth)acrylate, 3-chloro-2-hydroxypropyl(meth)acrylate, 3,5-dihydroxypentyl(meth)acrylate, 1-hydroxymethyl-4-(meth)acryloylmethyl cyclohexane, 2-hydroxy-3-phenoxypropyl(meth)acrylate, 1-methyl-2-acryloyloxypropyl phthalic acid, 2-acryloyloxyethyl-2-hydroxyethyl phthalic acid, 1-methyl-2-acryloyloxyethyl-2-hydroxypropyl phthalic acid, 2-acryloyloxyethyl-2-hydroxy-3-chloropropyl phthalic acid, ARONIX M-554, M-154, M-555, M-155 and M-158 (trade name, manufactured by TOAGOSEI CO., LTD.), BLEMMER PE-200, PE-350, PP- 500, PP-800, PP-1000, 70PEP-350B and 55PET800 (trade name, manufactured by NOF CORPORATION), and a lactone-modified acrylate having the following structure.

CH₂═CRCOOCH₂CH₂[OC(═O)C₅H₁₀]ₙOH (R is H or Me, n is 1 to 5)

When a hydroxyl group-containing (meth)acrylate is used as a monomer having a hydroxyl monomer, a raw material from which a bifunctional acrylate that is generated as a by-product upon synthesis of the hydroxyl group-containing (meth)acrylate has been removed may be used, from the viewpoint of synthesizing a high-molecular polymer.

The purification of the raw material is preferably conducted by distillation or column purification, more preferably by a method of purification in which the following processes (I) to (IV) are conducted in this order:

(I) dissolving in water a mixture of hydroxyl group-containing (meth)acrylate and a bifunctional acrylate that is a bi-product generated in the synthesis of the hydroxyl group-containing (meth)acrylate;

(II) adding a first organic solvent that separates from water, to the obtained aqueous solution, and then separating the phase including the first organic solvent and the bifunctional acrylate from the aqueous phase;

(III) dissolving, in the aqueous phase, a compound having higher water solubility than that of the hydroxyl group-containing (meth)acrylate; and

(IV) adding a second organic solvent to the aqueous phase to extract the hydroxyl group-containing (meth)acrylate, and then condensing the same.

Examples of the monomer having an epoxy group include glycidyl (meth)acrylate, and CYCLOMER A and M (trade name, manufactured by DAICEL CHEMICAL INDUSTRIES, LTD.).

Examples of the monomer having an isocyanate group include KARENZ AOI and MOI (trade name, manufactured by SHOWA DENKO K.K.)

The polymer used in the method iii) may further include other copolymerization component.

In the method iii), the type of the monomer having a polymerizable group to be reacted with the polymer having a reactive group may change according to the type of the reactive group in the polymer. Examples of the combination of the reactive group in the polymer and the functional group in the monomer are shown below.

| Reactive group | Functional |
|---|---|
| in the polymer | group in the monomer |
| carboxyl group | carboxyl group |
| carboxyl group | epoxy group |
| carboxyl group | isocyanate group |
| carboxyl group | halogenated benzyl group |
| hydroxyl group | carboxyl group |
| hydroxyl group | epoxy group |
| hydroxyl group | isocyanate group |
| hydroxyl group | halogenated benzyl group |
| isocyanate group | hydroxyl group |
| isocyanate group | carboxyl group |
| epoxy group | carboxyl group |

Examples of the monomer having the aforementioned functional group include acrylic acid, glycigyl acrylate, CYCLOMER A (trade name, manufactured by DAICEL CHEMICAL INDUSTRIES, LTD.), KARENZ AOI (trade name, manufactured by SHOWA DENKO K.K.), methacrylic acid, glycidyl methacrylate, CYCLOMER M (trade name, manufactured by DAICEL CHEMICAL INDUSTRIES, LTD.) and KARENZ MOI (trade name, manufactured by SHOWA DENKO K.K.)

In the specific polymer as synthesized according to the aforementioned method in the invention, the ratios of the polymerizable group-containing unit and the ionic interactive group-containing unit are preferably in the aforementioned range with respect to all of the copolymerization units. The following embodiments are preferred in particular.

In the specific polymer, the content ratio of a non-dissociative interactive group-containing unit is from 40% by mol to 60% by mol, and the content ratio of a radical polymerizable unit is from 10% by mol to 20% by mol, and the content ratio of an ionic interactive group-containing unit is 30% by mol to 50% by mol, which is a most preferable embodiment.

Further, a value of ionic polarity (or acid value) of the specific polymer is preferably in the range of from 1.5 mmol/g to 10.0 mmol/g, more preferably from 1.7 mmol/g to 5.0 mmol/g, yet more preferably from 1.9 mmol/g to 5.0 mmol/g, and further preferably 2.5 mmol/g to 4.5 mmol/g. When the acid value is in this range, a balance between developability with an aqueous solution and suppression of reduction in adhesiveness over time under hot and humid conditions can be achieved.

Further, the number of optimal units and the value of ionic polarity vary depending on a molecular weight of a unit having an ionic interactive group. In this case, optimization of the value of ionic polarity so as to be within the above range is given priority.

Further, the unit contained in the specific polymer is not limited to the aforementioned two kinds of units, or three kinds of units including a unit containing a desirable non-dissociative interactive group. For example, when the specific polymer is synthesized, in a case in which a polymerizable group is reacted with a polymer to introduce therein, it may be difficult to introduce 100% of the polymerizable group as calculated. As a result, in some cases, a small amount of unreacted portions remains in a copolymerization unit to which the polymerizable group is to be introduced. In this case, there is a possibility that a third or fourth unit free from both a polymerizable group and an ionic polar group may be formed.

The weight average molecular weight of the specific polymer according to the invention is preferably from 3,000 to 150,000, and more preferably from 5,000 to 100,000. In particular, from the viewpoint of polymerization sensitivity, the weight average molecular weight of the specific polymer according to the invention is preferably 20,000 or more. Further, in view of increasing the thickness of the layer to be plated that is obtained by photo-curing so that more amount of plating catalyst or a precursor thereof can be adsorbed to the layer, the weight average molecular weight of the specific polymer according to the invention is particularly preferably 60,000 or more. The upper limit of the weight average molecular weight is preferably 150,000.

The weight average molecular weight here refers to a value as measured by GPC (solvent: N-methyl pyrrolidone) in terms of polystyrene. For example, the weight average molecular weight can be measured under the following conditions.

Guard column: TOSOH TSK GUARD COLUMN SUPER AW-H (trade name, manufactured by TOSOH CORPORATION)

Separating column: TOSOH TSKGEL SUPER AWM-H (trade name, manufactured by TOSOH CORPORATION, three columns of 6.0 mm×15 cm are connected)

Eluting agent: N-methyl pyrrolidone (containing 10 mM of LiBr)

Flow rate: 0.35 mL/min

Detection method: RI

Temperatures: 40° C. at column, 40 ° C. at inlet, and 40 ° C. at RI

Sample concentration: 0.1 wt %

Injection amount: 60 μL

Regarding the polymerization degree, the specific polymer according to the invention is preferably a 20-mer or more, more preferably a 30-mer or more. Further, the specific polymer according to the invention is preferably a 1,500-mer or less, more preferably a 1,000-mer or less.

In the composition for forming a layer to be plated according to the invention, a mixed solvent of water and water-soluble flammable liquid is used as a solvent, as described below.

The specific polymer described above is preferably contained in the range of from 1% by mass to 20% by mass, and more preferably from 2% by mass to 10% by mass, with respect to a total amount of the composition.

Mixed Solvent Containing from 20% By Mass to 99% By Mass of Water-Soluble Flammable Liquid and Water

The composition for forming a layer to be plated according to the invention contains, as well as a specific polymer described above, a mixed solvent containing both a water-soluble flammable liquid and water, which is capable of dissolving the specific polymer. It is necessary that the mixed solvent containing the water-soluble flammable liquid and water used in the invention contains from 20% by mass to 99% by mass of the water-soluble flammable liquid in terms of a total solvent. Herein, a mixed solvent in which the remainder other than the water-soluble flammable liquid is water is preferred. The content of the water-soluble flammable liquid in the mixed solvent is preferably in the range of from 30% by mass to 80% by mass, and more preferably from 35% by mass to 60% by mass.

### Water-Soluble Flammable Liquid

The water-soluble flammable liquid used in the mixed solvent of the water-soluble flammable liquid and water is not specifically limited, so long as the flammable liquid dissolves 1% by mass or more thereof in water at ordinary temperature (25° C.). Further, the flammable liquid described in the present specification refers to flammable liquids as recited in the Fire Services Act.

Examples of the water soluble flammable solvent include organic solvents such as ketone-based solvents, ester-based solvents, alcohol-based solvents, ether-based solvents, amine-based solvents, thiol-based solvents and halogen-based solvents.

Examples of the ketone-based solvents include 4-hydroxy-4-methyl-2-pentanone, γ-butyrolactone and hydroxyacetone.

Examples of the ester-based solvents include 2-(2-ethoxyethoxy)ethyl acetate, ethylene glycol monomethyl ether acetate, diethylene glycol monoethyl ether acetate, methyl cellosolve acetate, 2-hydroxyethyl acrylate, hydroxypropyl acrylate, methyl glycolate and ethyl glycolate.

Examples of the alcohol-based solvent include methanol, ethanol, 1-methoxy-2-propanol, isopropyl alcohol, normal propyl alcohol, 3-acetyl-1-propanol, 2-(allyloxy)ethanol, 1-pentanol, 3-methyl-1-butanol, n-hexanol, 1-heptanol, 2-ethyl-1,3-hexanediol, 2-aminoethanol, 2-amino-2-methyl-1-propanol, (±)-2-amino-1-propanol, 3-amino-1-propanol, 2-dimethylaminoethanol, 2,3-epoxy-1-propanol, ethylene glycol, 2-fluoroethanol, diacetone alcohol, 2-methylcyclohexanol, 4-hydroxy-4-methyl-2-pentanone, glycerin, 2,2′,2″-nitrilotriethanol, 2-pyridine methanol, 2,2,3,3-tetrafluoro-1-propanol, 2-(2-aminoethoxy)ethanol, 2-[2-(benzyloxy)ethoxy]ethanol, 2,3-butanediol, 2-butoxyethanol, 2,2′-thiodiethanol, 1,3-butanediol, 1,4-butanediol, 2,3-butanediol, 2-methyl-2,4-pentanediol, 1,3-propanediol, diglycerin, 2,2′-methyliminodiethanol and 1,2-pentanediol. In addition, the alcohol-based solvent includes alcohol derivatives such as 3-amino-1-propanol, trifluoroethyl methacrylate, and pentadecafluoro octanol.

Examples of the ether-based solvent include bis(2-ethoxyethyl)ether, bis[2-(2-hydroxyethoxy)ethyl]ether, 1,2-bis(2-methoxyethoxy)ethane, bis[2-(2-methoxyethoxy)ethyl]ether, bis(2-methoxyethyl)ether, 2-(2-butoxyethoxy)ethanol, 2-[2-(2-chloroethoxy)ethoxy]ethanol, 2-ethoxyethanol, 2-(2-ethoxyethoxy)ethanol, 2-isobutoxy ethanol, 2-(2-isobutoxyethoxy)ethanol, 2-isopropoxyethanol, 2-[2-(2-methoxyethoxy)ethoxy]ethanol, 2-(2-methoxyethoxy)ethanol, 1-ethoxy-2-propanol, 1-methoxy-2-propanol, tripropylene glycol monomethyl ether, methoxy acetate and 2-methoxy ethanol.

Examples of the glycol-based solvents include diethylene glycol, triethylene glycol, ethylene glycol, hexaethylene glycol, propylene glycol, dipropylene glycol and tripropylene glycol.

Examples of the amine-based solvent include N-methyl-2-pyrolidone and N,N-dimethyl formamide.

Examples of the thiol-based solvent include mercaptoacetic acid and 2-mercaptoethanol.

Examples of the halogen-based solvent include 3-bromobenzylalcohol, 2-chloroethanol and 3-chloro-1,2-propanediol.

Examples of the solvent contained in the water-soluble flammable liquid other than the above-described solvent include methyl lactate, ethyl lactate, morpholine, N-ethyl morpholine, formic acid, and acetic acid.

The water-soluble flammable liquid contained in the mixed solvent may be used singly or by mixing two or more kinds so long as a total content of the water-soluble flammable liquid is in the aforementioned range.

Water-Alcohol Mixed Solvent

Examples of the optimal embodiment of the mixed solvent containing both water and a water-soluble flammable liquid includes a water-alcohol mixed solvent using an alcohol-based solvent as the water-soluble flammable liquid.

It is necessary that the water alcohol solvent contains 20% by mass to 99% by mass of alcohol in the total solvent. Herein, a mixed solvent is preferred in which the remainder other than alcohol is water. The content of alcohol in the mixed solvent is preferably in the range from 30% by mass to 80% by mass, and more preferably from 35% by mass to 60% by mass.

The alcohol-based solvent used in the mixed solvent includes the alcohols and alcohol derivatives described above, and preferable examples include alcohol-based solvents such as methanol, ethanol, propanol, ethylene glycol, glycerine, propylene glycol monomethyl ether, and 1-methoxy-2-propanol.

The alcohol-based solvent contained in the mixed solvent may be used singly or by mixing two or more kinds

Further, in a water-alcohol mixed solvent containing alcohol and water that is an optimal solvent in the invention, the alcohol may be used together with acids such as acetic acid; or a ketone-based solvent such as acetone, methyl ethyl ketone and cyclohexanone; an amide-based solvent such as formamide, dimethyl acetamide, and N-methylpyrrolidone; a nitrile-based solvent such as acetonitrile and propyronitrile; an ester-based solvent such as methyl acetate and ethyl acetate; or a carbonate-based solvent such as dimethyl carbonate and diethyl carbonate, which are other water-soluble flammable liquids not included in the alcohol. As a solvent other than these solvents, an ether-based solvent, a glycol-based solvent, an amine-based-solvent, a thiol-based solvent, and a halogen-based solvent may be used together with the alcohol. Even in the case of using these solvents for combination, it is necessary that the content of alcohol in the mixed solvent is in the range of from 20% by mass to 99% by mass.

Further, in the case of producing the composition for forming a layer to be plated, that contains a specific polymer having a cyano group which is a non-polar interactive group, from the viewpoints of easy handleability, a solvent to be combined has a boiling point of preferably from 40° C. to 200° C., more preferably from 60° C. to 158° C., and further preferably from 65° C. to 120° C.

The water-soluble flammable solvent for preparing a mixed solvent used in the invention preferably has the boiling point of from 60° C. to 158° C., and more preferably from 65° C. to 120° C., from the viewpoints of ease of evaporation. Especially favorable examples of an alcohol-based solvent capable of mixing with water include methanol (boiling point: 65° C.), ethanol (boiling point: 78° C.), isopropyl alcohol (boiling point: 82° C.), n-propyl alcohol (boiling point: 97° C.), and 1-methoxy-2-propanol (boiling point: 119° C.).

In the invention, as described above, a mixed solvent of water and water-soluble flammable liquid is used, but the flash point of the water-soluble flammable liquid is preferably 30° C. or higher, more preferably 40° C. or higher, and most preferably 60° C. or higher, from the viewpoints of ease of operation.

The flash point used in the invention refers to a value as measured based on JIS-K 2265 (Tag closed cup method).

Water

The water used as a solvent in the composition for forming a layer to be plated according to the invention preferably includes no impurities. For example, RO water, deionized water, distilled water and purified water are preferred. Among these, deionized water and distilled water are more preferred.

Additives for Improving Solubility of Specific Polymer

In the composition for forming a layer to be plated according to the invention, a mixed solvent of a water-soluble flammable liquid and water containing at least 20% by mass to 99% by mass of the water-soluble flammable liquid, and water is used. Further, an additive may be used for increasing solubility of a specific polymer.

In the invention, in a case in which a specific polymer acting as a solute has an acidic group such as a carboxylic group as an ionic polar group, the acidic group is converted into a salt thereof such as sodium carboxylate, so that the specific polymer becomes easy to dissolve in a water-alcohol mixed solvent. As an additive used for converting the carboxylic group into sodium carboxylate, a basic compound may be used. Specific examples of the basic compound to be used include sodium hydrogen carbonate, sodium carbonate, sodium hydroxide, tetramethyl ammonium hydroxide, potassium hydrogen carbonate, potassium carbonate, potassium hydroxide, lithium hydrogen carbonate, lithium carbonate, lithium hydroxide, methylamine, dimethyl amine, trimethyl amine, ethylamine, diethyl amine, triethyl amine, butyl amine, dibutyl amine, tributyl amine, ammonia, diazabicycloundecene (DBU), and diazabicyclononene (DBN). Among them, preferable additives include alkali metal salts such as a sodium salt, a lithium salt, and a potassium salt. From the viewpoints of degree of water solubilization and optimal basicity, sodium hydrogen carbonate, sodium carbonate and sodium hydroxide are particularly preferred.

Water-Insoluble Photopolymerization Initiator

The composition for forming a layer to be plated according to the invention contains a water-insoluble photopolymerization initiator in order to increase sensitivity to energy application.

The water-insoluble photopolymerization initiator of the invention means a compound, a precipitation of which is visually observed when 0.1% by mass of photopolymerization initiator is added to water at ordinary temperature (25° C.), followed by stirring, and then left to stand for 10 minutes.

The water-insoluble photopolymerization initiator to be used is preferably a compound, an absorption wavelength region of which has an absorbance peak in the range of from 250 nm to 400 nm, and more preferably from 280 nm to 360 nm.

Specifically, examples of the water-insoluble photopolymerization initiator favorably used in the invention include benzoin compounds and derivatives thereof such as benzoin ethyl ether, methyl benzoin ether, ethyl benzoin ether, butyl benzoin ether, and benzoin isopropyl ether; benzyl ketal-based compounds and derivatives thereof such as benzyl dimethyl ketal; hydroxy ketone-based compounds and derivatives thereof such as 1-hydroxy cycohexyl phenyl ketone; benzophenone-based compounds and derivatives thereof such as benzophene, 4-phenyl-benzophenone, 4-chlorobenzophenone; acetophenone-based compounds and derivatives thereof such as michler's ketone, anthrone, 1-benzoyl cyclohexanon-1-ol, 2-hydroxy-2-2-dimethyl acetophenone, 2,2-dimethoxy-2-phenylacetophenone; α-aminoalkyl phenone-based compounds and derivatives thereof such as 2-benzyl-2-dimethyl amino-1-(4-morpholinophenyl)-butanone-1,2-benzyl-2-dimethyl amino-1-(4-morpholinophenyl)-butanone-1,2-dimethyl amino-2-(4-(methyl-benzyl)-1-(4-morpholin-4-yl-phenyl)-butan-1-one; bisacyl phosphinoxide-based compounds and derivatives thereof such as bis(2,4,6-trimethylbenzoyl)-phenylphosphinoxide, bis(2,6-dimethoxybenzoyl)-2,4,4-trimethylpentyl phosphinoxide; acyl phosphinoxide-based compounds and derivatives thereof such as 2,4,6-trimethylbenzoylphenyl ethoxyphosphinoxide, 2,4,6-trimethylbenzoyl diphenyl phosphinoxide, ethyl-2,4,6-trimethylbenzoylphenyl phosphinate, and bisacyl phosphinoxide; thioxanthone-based compounds and derivatives thereof such as isopropyl thioxanthone, 2,4-diethylthioxanthone; anthraquinone-based compounds and derivatives thereof such as ethylanthraquinone, 2-methyl-1-[4-(methylthio)phenyl]-2-morpholinopropan-1-one, β-methylanthraquinone, and tert-butyl anthraquinone; oxime ester-based compounds and derivatives thereof such as 1,2-octanedione, 1-(4-(phenylthio)-2-(o-benzoyloxime)), ethanone, 1-(9-ethyl-6-(2-methylbenzoyl)-9H-carbazol-3-yl)-1-(o-acetyloxime). The water-insoluble photopolymerization initiator is not limited, so long as it is a water-insoluble initiator.

Among them, preferable examples include 2-benzyl-2-dimethyl amino-1-(4-morpholinophenyl)-butanone-1,2-dimethylamino-2-(4-(methyl-benzyl)-1-(4-morpholine-4-yl-phenyl)-butan-1-one, 1,2-octanedione, 1-(4-(phenylthio)-2-(o-benzoyloxime)), ethanone, and 1-(9-ethyl-6-(2-methylbenzoyl)-9H-carbazol-3-yl)-1-(o-acetyloxime).

In the composition for forming a layer to be plated according to the invention, the water-insoluble photopolymerization initiator may be used singly or in combination of two or more kinds At that time, at least one photopolymerization initiator having a preferable absorbance peak and at least one photopolymerization initiator having another absorbance peak may be combined.

A content of the water-insoluble photopolymerization initiator is in the range of preferably from 1% by mass to 20% by mass, and more preferably from 5% by mass to 10% by mass, with respect to the specific polymer.

Sensitizer

The composition for forming a layer to be plated according to the invention may include a sensitizer in addition to the above-described photopolymerization initiator, in order to further improve the sensitivity of the composition to light when energy is applied by light irradiation.

The sensitizer is exited by active energy rays and interacts with the photopolymerization initiator (for example, energy transfer or electron transfer), whereby generation of radicals can be promoted.

The sensitizer which may be used in the invention is not specifically limited, and can be suitably selected from known sensitizers. Examples of the sensitizer include benzophenone derivatives, benzanthrone derivatives, quinones, anthraquinones, aromatic nitro compounds, napthothiazoline derivatives, benzothiazoline derivatives, xanthones, napthothiazol derivatives, ketocoumarin compounds, benzothiazol derivatives, napthofuranone compounds, benzoin compounds, acetophenone compound, and fluorenone compounds.

Specifically, examples thereof include michler ketone, N,N′-diethyl aminobenzophenone, benzanthrone, (3-methyl-1,3-diaza-1,9-benz)anthronepicramide, 5-nitroacenaphthene, 2-nitrofluorene, 2-dibenzoylmethylene-3-methylnapthothiazoline, 3,3-carbonyl-bis(7-diethyl aminocoumarin), 2,4,6-triphenyl thiapyrylium perchlorate, 2-(p-chlorobenzoyl)napthothiazol, benzoin, benzoin methyl ether, benzoin ethyl ether, 2,2-dimethoxy-2-phenylacetophenone, 9-fluorenone, 2-chloro-9-fluorenone, 2-methyl-9-fluorenone, 9,10-anthraquinone, 2-ethyl-9,10-anthraquinone, 2-t-butyl-9,10-anthraquinone, 2,6-dichloro-9,10-anthraquinone, xanthone, 2-methylxanthone, 2-methoxyxanthone, dibenzal acetone, p-(dimethylamino)phenylstyryl ketone, and p-(dimethyl amino)phenyl-p-methylstyryl ketone.

Further, another examples include merocyanine dyes, such as 2-(heterocyclyl carbonylmethylene)benzo (or naphtho)thiazoline, 2-(diheterocyclecarbonylmethylene)benzo (or naptho)thiazonine, 2-dibenzoylmethylenebenzo (or naptho)thiazoline, and further including 2-[bis(2-furoyl)methylene]-3-methylbenzothiazoline, 2-[bis(2-thenoyl)methylene]-3-methylbenzothiazonine, 2-[bis(2-furoyl)methylene]-3-methylnapthothiazoline, 2-[bis(2-furoyl)methylene]-3-methylnapthothiazoline, 2-(2-furoyl)methylene-3-methylbenzothiazoline, 2-benzoylmethylene-3-methylbenzothiazoline, 2-bis(benzoylmethylene)benzothiazoline, 2-bis(benzoylmethylene)napthothiazoline, and thiazole, benzothiazol, napthothiazol, benzoselenazole-based sensitizing dyes having a thiobarbituric acid ring.

Other examples of the sensitizer include sensitizers having a basic nucleus, sensitizers having an acidic nucleus, and sensitizers having a fluorescent whitener.

These sensitizers is preferably included in the composition for forming a layer to be plated according to the invention at an amount of from about 1% by mass to about 30% by mass with respect to the specific polymer.

Surfactant

The composition for forming a layer to be plated according to the invention may include a surfactant.

The surfactant that may be used in the invention is not particularly limited as long as it is soluble to the aforementioned solvent. Examples of such a surfactant include anionic surfactants such as sodium n-dodecylbenzenesulfonate; cationic surfactants such as n-dodecyltrimethylammonium chloride; nonionic surfactants such as polyoxyethylene nonylphenol ether (examples of commercially available products include EMULGEN 910, trade name, manufactured by KAO CORPORATION), polyoxyethylene sorbitan monolaurate (examples of commercially available products include TWEEN 20, trade name, manufactured by TOKYO CHEMICAL INDUSTRY CO., LTD.), and polyoxyethylene lauryl ether.

Plasticizer

The composition for forming a layer to be plated according to the invention may include a plasticizer if needed. The plasticizer may be selected from commonly-used plasticizers. As the plasticizer, it is also possible to use a high boiling solvent such as esters of phthalic acid (dimethyl ester, diethyl ester, dibutyl ester, di-2-ethylhexyl ester, di-normal-octyl ester, diisononyl ester, dinonyl ester, diisodecyl ester, butylbenzyl ester, and the like), esters of adipic acid (dioctyl ester, diisononyl ester, and the like), esters of azelaic acid (dioctyl ester and the like), esters of sebacic acid (dibutyl ester, dioctyl ester, and the like), tricresyl phosphate, tributyl acetylcitrate, epoxidized soybean oil, trioctyl trimellitate, chlorinated paraffins, dimethylacetamide, and N-methylpyrrolidone.

Polymerization Inhibitor

A polymerization inhibitor may be added to the composition for forming a layer to be plated according to the invention, as necessary. Examples of the polymerization inhibitor that may be used include hydroquinones such as hydroquinone, di-tertiary-butyl hydroquinone and 2,5-bis(1,1,3,3-tetramethylbutyl)hydroquinone; phenols such as p-methoxyphenol and phenol; benzoquinones; free radicals such as TEMPO (2,2,6,6-tetramethyl-1-piperidinyloxy free radical) and 4-hydroxy-TEMPO; phenothiazines; nitrosoamines such as N-nitrosophenylhydroxyamine and an aluminum salt thereof; and catechols.

Curing Agent and Curing Accelerator

In a case in which a layer formed from the composition for forming a layer to be plated according to the invention is provided on an adhesion-aiding layer (described later), a curing agent and/or a curing accelerator may be added to the composition in order to accelerate the curing of the adhesion-aiding layer. For example, when an epoxy compound is included in the adhesion-aiding layer, examples of the curing agent and/or curing accelerator include polyaddition-type compounds such as aliphatic polyamines, alicyclic polyamines, aromatic polyamines, polyamides, acid anhydrides, phenols, phenol novolacs, polymercaptans, compounds having two or more active hydrogen atoms; and catalyst-type compounds such as aliphatic tertiary amines, aromatic tertiary amines, imidazole compounds, and Lewis acid complexes.

Examples of those that initiate curing upon application of heat, light, humidity, pressure, acid, base or the like include diethylenetriamine, triethylenetetramine, tetraethylenepentamine, diethylaminopropylamine, polyamideamine, menthenediamine, isophoronediamine, N-aminoethylpiperazine, 3,9-bis(3-aminopropyl)-2,4,8,10-tetraoxyspiro(5,5)undecane adduct, bis(4-amino-3-methylcyclohexyl)methane, bis(4-aminocyclohexyl)methane, m-xylenediamine, diaminodiphenylmethane, m-phenylenediamine, diaminodiphenylsulfone, dicyandiamide, adipic acid dihydrazide, phthalic anhydride, tetrahydrophthalic anhydride, hexahydrophthalic anhydride, methyltetrahydrophthalic anhydride, methylhexahydrophthalic anhydride, methylnadic anhydride, dodecylsuccinic anhydride, chlorendic anhydride, pyromellitic anhydride, benzophenonetetracarboxylic acid anhydride, ethylene glycol bis(anhydro trimellitate), methylcyclohexene tetracarboxylic acid anhydride, trimellitic anhydride, polyazelaic anhydride, phenol novolac, xylylene novolac, bisphenol A novolac, triphenylmethane novolac, biphenyl novolac, dicyclopentadiene phenol novolac, terpene phenol novolac, polymercaptan, polysulfide, 2,4,6-tris(dimethylaminomethyl)phenol, 2,4,6-tris(dimethylaminomethyl)phenol-tri-2-ethylhexanoic acid salt, benzyldimethylamine, 2-(dimethylaminomethyl)phenol, 2-methylimidazole, 2-ethyl-4-methylimidazole, 2-undecylimidazole, 2-heptadecylimidazole, 2-phenylimidazole, 1-benzyl-2-methylimidazole, 1-cyanoethyl-2-methylimidazole, 2,4-diamino-6-(2-methylimidazolyl-(1))-ethyl S-triazine, BF₃ monoethylamine complex, Lewis acid complexes, organic acid hydrazides, diaminomaleonitrile, melamine derivatives, imidazole derivatives, polyamine salts, aminimide compounds, aromatic diazonium salts, diaryliodonium salts, triarylsulfonium salts, triarylselenium salts, ketimine compounds, and the like.

The curing agent and/or the curing accelerator is preferably added to the composition for forming a layer to be plated according to the invention at the amount of from 0 to about 50% by mass with respect to the non-volatile components that remain after the solvent has been removed, from the viewpoint of coating suitability of the composition, adhesion of the layer to the substrate or the plating film, or the like.

The curing agent and/or the curing accelerator may also be added to an adhesion-aiding layer. In this case, it is preferable that a total amount of the curing agent and/or the curing accelerator that are (is) added to both the adhesion-aiding layer and the composition for forming a layer to be plated satisfies the above range.

Other Additives

The composition for forming a layer to be plated according to the invention may further include other additives such as a rubber component (such as CTBN), a flame retardant (such as a phosphorus-based flame retardant), a diluent, a thixotropic agent, a pigment, a defoaming agent, a leveling agent, or a coupling agent. These additives may also be added to the adhesion-aiding layer, as necessary.

The composition for forming a layer to be plated can be prepared by appropriately mixing the specific polymer and other components such as the above. By using this composition, it is possible to optimize the properties of the layer formed from the composition, such as the thermal expansion coefficient, glass transition temperature, Young's modulus, Poisson's ratio, rupture stress, yield stress, or thermal decomposition temperature. In particular, it is preferred that the rupture stress, yield stress and thermal decomposition temperature be as high as possible.

The thermal durability of the layer formed from the composition according to the invention can be measured by a temperature cycle test, a thermal aging test, a reflow test, or the like. For example, with respect to the state of thermal decomposition, if the mass reduction after being exposed to the environment of 200° C. for 1 hour is 20% or less, it can be evaluated that the layer has a sufficient level of thermal durability.

The composition for forming a layer to be plated according to the invention is characterized in that the specific polymer and water-insoluble photopolymerization initiator which are essential ingredients of the invention are dissolved and contained in a mixed solvent of water and water-soluble flammable liquid described above. That is to say, the water-insoluble photopolymerization initiator is dissolved in the mixed solvent of water and a water-soluble flammable liquid used in the invention, so that the composition of the invention is in the state of a homogeneous solution. Accordingly, a composition in which a water-insoluble photopolymerization initiator and/or a sensitizing dye is dispersed in a solid state is not fallen into the category of the composition for forming a layer to be plated according to the invention.

In the invention, the composition for forming a layer to be plated is a homogenous solution in which the specific polymer and the photopolymerization initiator are dissolved, and thereby an excellent patterned layer to be plated with higher resolution is formed in comparison with a solid dispersion liquid containing insoluble materials.

The fact that the specific polymer and the water-insoluble photopolymerization initiator are dissolved is confirmed as follows.

The composition for forming a layer to be plated, that is, a composition that is obtained by a method in which 1% by mass to 20% by mass of the specific polymer and the water-insoluble photopolymerization initiator are added to a solvent containing both a water-soluble flammable liquid in the proportion of 20% by mass to 99% by mass with respect to a total solvent and water, and dissolved therein while stirring, is prepared and then left to stand at room temperature (25° C.) for 10 minutes. Then, visual observation provides a confirmation of dissolution. In a case in which the composition (solution) having been prepared and then left to stand for 10 minutes is subjected to a visual confirmation, when no precipitation is found, the composition is determined as “dissolved”, and in contrast, precipitation is found, the composition is determined as “not dissolved”.

Method of Producing Metal Pattern Material

The method of producing a metal pattern material according to the invention include: (1) coating the composition for forming a layer to be plated according to the invention on or above a substrate to form a coated film for forming a layer to be plated and applying energy to the coated film for forming a layer to be plated and curing the coated film at a portion to which the energy has been applied; (2) forming a patterned layer by developing an uncured portion of the composition with an aqueous solution; (3) applying a plating catalyst or a precursor thereof to the patterned layer; and (4) plating the plating catalyst or the precursor thereof.

In the following, each of the steps (1) to (4) will be explained.

Step (1)

In step (1), after coating the composition for forming a layer to be plated according to the invention on or above a substrate to form a coated film for forming a layer to be plated, energy is applied to a portion of the coated film to cure the coated film at this portion.

In one preferable embodiment, the specific polymer in the layer to be plated is bound to the substrate via a radical polymerizable group included in the molecule of the specific polymer.

When the composition is coated on the substrate, the coating amount of the composition is preferably from 0.1 to 10 g/m², more preferably from 0.5 to 5 g/m², in terms of solid content, from the viewpoint of achieving a sufficient level of interaction with the plating catalyst or a precursor thereof

When the composition including the specific polymer is coated on the substrate and dried to form a layer including the specific polymer, the layer may be left to stand at 20 to 40° C. for 0.5 to 2 hours to remove the residual solvent, between the processes of coating and drying.

The coating of the composition for forming a layer to be plated according to the invention on the substrate may be performed by immersing the substrate in the composition. However, from the viewpoint of handleability or production efficiency, it is preferred to form a layer composed of the composition on the surface of the substrate (or the surface of the adhesion-aiding layer) by a coating method.

When the substrate is a resin film and the layer is formed from the composition on both sides of the resin film, the coating method is also preferred in view of ease of formation of the layer on both sides of the substrate at the same time.

Application of Energy

In step (1), after coating the composition for forming a layer to be plated according to the invention on the substrate, energy is applied to the composition that has been coated on the substrate.

The application of energy is preferably conducted by heating, exposure or the like. Heating and exposure may be used together. In view of ease of formation of a patterned image, exposure is preferred.

For exposure, light irradiation can be conducted using a UV lamp, visible rays or the like. Examples of the light source include a mercury lamp, a metal halide lamp, a xenon lamp, a chemical lamp, and a carbon arc lamp. Examples of radiation rays include electron beams, X-rays, ion beams, and far-infrared rays. Moreover, g-line rays, i-line rays, Deep-UV rays, high-density energy beams (laser beams) are also applicable.

Specific and favorable embodiments of commonly-used energy application include scan-exposure using infrared laser beams, high-illuminance flash exposure using a xenon discharge lamp or the like, and exposure with an infrared lamp.

From the viewpoints of sensitivity and resolution, exposure is preferably carried out at the exposure wavelength of from 250 nm to 400 nm, and more preferably from 280 nm to 370 nm.

Exposure time varies depending on the reactivity of the specific polymer and light source, but the exposure time is generally in a range from 1 second to 5 hours in this whole exposure process. For example, in a case in which a laser is used in the exposure process, if exposure is carried out so that ten lines each having the length of 10 cm are drawn with a laser having the beam diameter of from 10 μm to 300 μm, lines may be drawn in the period of from several seconds to several minutes, and exposure time per line may be less than 1 second.

Further, exposure energy may be in the range of from about 10 to 8000 mJ, and preferably from 100 mJ to 3000 mJ.

When patterned heating is conducted as a method of applying energy, exposure with infrared rays or far-infrared rays can be performed.

Further, heating can be carried out as an additive energy application after pattern exposure. In a case in which the additive heating process is performed, for example, an air blowing drier, an oven, a hot plate, an infrared drier, or a heating drum can be used.

When energy is applied to the composition in such a manner as described above, curing reaction of the specific polymer occurs only at a portion to which energy has been applied. As a result, only the composition at this portion is cured.

Substrate

The substrate used in step (1) is not particularly limited as long as it can retain its shape, and preferably has a surface capable of chemically bonding to the specific polymer. Specifically, the substrate itself may have an ability of generating radicals upon exposure with light, or the substrate may include a base member and, provided on the base member, an intermediate layer (such as an adhesion-aiding layer as described later) having an ability of generating radicals upon exposure with light.

Base Member and Substrate

The base member used in the invention is preferably a plate-shaped and dimensionally stable material. Examples thereof include a paper, a paper laminated with a plastic (such as polyethylene, polypropylene or polystylene), a metal plate (such as aluminum, zinc or copper), a plastic film (such as cellulose diacetate, cellulose triacetate, cellulose propionate, cellulose butyrate, cellulose acetate, cellulose nitrate, polyethylene terephthalate, polyethylene, polystyrene, polypropylene, polycarbonate, polyvinyl acetal, polyimide, epoxy, bismaleimide resin, polyphenylene oxide, liquid crystal polymer, polytetrafluoroethylene or acrylonitrile-butadiene-styrene copolymer (ABS resin)), and a paper or plastic film on which a metal as mentioned above is laminated or evaporated. In the invention, a base member formed from an epoxy resin, a polyimide resin, an ABS resin, or a polycarbonate resin is preferred.

When the surface of the base member has a function of forming a state in which the specific polymer is directly chemically bound thereto, the base member itself may be used as the substrate.

A base member including a polyimide having a polymerization initiation site in the skeleton thereof, as described in paragraphs [0028] to [0088] of JP-A No. 2005-281350, may also be used for the substrate in the invention.

The metal pattern material produced by the method of producing a metal pattern material according to the invention may be applied to a semiconductor package, various kinds of electrical wiring boards, and the like. When the metal pattern material is used in such applications, it is preferable to use a substrate including an insulating resin as described below. Specifically, it is preferable to use a substrate formed from an insulating resin, or a substrate including a base member and, provided on the base member, a layer formed from an insulating resin.

Known insulating resin composition may be used to obtain a substrate formed from an insulating resin or a layer formed from an insulating resin. The insulating resin composition may include an additive of various kinds according to purposes in addition to the resin as a main component. For example, a polyfunctional acrylate monomer may be added for the purpose of increasing the strength of insulating layer, or inorganic or organic particles may be added for the purpose of increasing the strength of insulating layer and improving the electrical properties thereof.

Here, the “insulating resin” according to the invention refers to a resin having an insulating property within a tolerance level for use in known insulating films or insulating layers. Therefore, even if a resin is not an absolute insulating material, the resin may be favorably used in the present invention, as long as it has insulating properties according to purposes.

The insulating resin may be a thermosetting resin, a thermoplastic resin, or a mixture thereof. Specifically, examples of the thermosetting resin include epoxy resins, phenolic resins, polyimide resins, polyester resins, bismaleimide resins, polyolefin-based resins, isocyanate-based resins, and the like.

Examples of the epoxy resins include cresol novolac-type epoxy resins, bisphenol A-type epoxy resins, bisphenol F-type epoxy resins, phenol novolac-type epoxy resins, alkylphenol novolac-type epoxy resins, biphenol F-type epoxy resins, naphthalene-type epoxy resins, dicyclopentadiene-type epoxy resins, epoxides of a condensate formed from a phenol and an aromatic aldehyde having a phenolic hydroxyl group, triglycidyl isocyanurate, alicyclic epoxy resins, and the like. These resins may be used alone or may be used in combination of two or more kinds By including the insulating resin as mentioned above, excellent heat resistance or the like can be achieved.

Examples of the polyolefin-based resins include polyethylene, polystyrene, polypropylene, polyisobutylene, polybutadiene, polyisoprene, cycloolefin-based resins, copolymers of these resins, and the like.

Examples of the thermoplastic resins include phenoxy resins, polyether sulfone, polysulfone, polyphenylene sulfone, polyphenylene sulfide, polyphenyl ether, polyether imide, and polycarbonate.

Other thermoplastic resins include 1,2-bis(vinylphenylene)ethane resin, or a modified resin obtained from a 1,2-bis(vinylphenylene)ethane resin and a polyphenylene ether resin (described in Satoru Amou et al., Journal of Applied Polymer Science, Vol. 92, pp. 1252-1258 (2004)), liquid crystal polymers (for example, VECSTAR, trade name, manufactured by KURARAY CO., LTD.), fluorine resins (PTFE), and the like.

The thermoplastic resin and the thermosetting resin may be used alone or in combination of two or more kinds These resins may be combined for the purpose of compensating the defects of each resin so as to achieve better effects. For example, since a thermoplastic resin such as polyphenylene ether (PPE) has a low resistance to heat, this resin can be alloyed with a thermosetting resin or the like. Examples thereof include alloys of PPE with epoxy or triallyl isocyanate, and alloys of a PPE resin to which a polymerizable functional group has been introduced with another thermosetting resin.

Further, a cyanate ester is a resin that exhibits the most excellent dielectric properties among the thermosetting resins, but is typically used as a modified resin with an epoxy resin, a maleimide resin, a thermoplastic resin or the like, rather than being used as it is. Details of these resins are described in “Denshi Gijutsu (Electronic Technologies)” No. 2002/9, p. 35. Furthermore, a mixture of an epoxy resin and/or a phenolic resin as a thermosetting resin, and a phenoxy resin and/or polyethersulfone (PES) as a thermoplastic resin, may also be used for the purpose of improving dielectric properties.

The insulating resin composition may include a compound having a polymerizable double bond, such as an acrylate or methacrylate compound, particularly preferably a polyfunctional acrylate or methacrylate compound, in order to promote crosslinking reaction. Other examples of the compound containing a polymerizable double bond include those obtained by subjecting a part of a thermosetting resin or a thermoplastic resin (for example, an epoxy resin, a phenolic resin, a polyimide resin, a polyolefin resin, or a fluorine resin) to a (meth)acrylation reaction using methacrylic acid, acrylic acid or the like.

A composite (composition material) of a resin and other component may also be used as the insulating resin composition for the purpose of reinforcing the properties of a resin film, such as mechanical strength, heat resistance, weather resistance, flame retardancy, water resistance or electrical properties. Examples of the material that may be used to form a composite include paper, glass fiber, silica particles, phenol resins, polyimide resins, bismaleimide triazine resins, fluorine resins, polyphenylene oxide resins, or the like.

Further, as necessary, the insulating resin composition may be compounded with one or more kinds of filler for use in general resin materials for wiring boards. Examples of the filler include inorganic fillers such as silica, alumina, clay, talc, aluminum hydroxide and calcium carbonate, and organic fillers such as cured epoxy resin, crosslinked benzoguanamine resin and crosslinked acrylic polymer. Among them, silica is preferably used as the filler.

The insulating resin composition may also include one or more additives of various kinds as necessary, such as a colorant, a flame retardant, a tackifier, a silane coupling agent, an antioxidant, an ultraviolet absorbent, or the like.

When such a material as described above is added to the insulating resin composition, an addition amount of the material is preferably from 1 to 200% by mass, and more preferably from 10 to 80% by mass, with respect to the amount of the resin. If the addition amount is less than 1% by mass, effects on reinforcement of the aforementioned properties may not be achieved, while if the above amount is more than 200% by mass, properties that are inherent to the resin, such as strength, may deteriorate.

The substrate for use in the aforementioned applications is preferably formed from an insulating resin having a dielectric constant (relative dielectric constant) at 1 GHz of 3.5 or less, or formed from a base member and a layer formed from the above-described insulating resin that is formed on the base member. Further, the substrate is preferably formed from an insulating resin having a dielectric loss tangent at 1 GHz of 0.01 or less, or the substrate preferably has a base member and, provided on the base member, a layer formed from the insulating resin having a dielectric loss tangent at 1 GHz of 0.01 or less.

The dielectric constant and the dielectric loss tangent of an insulating resin can be measured by standard methods. For example, these properties can be measured by using a cavity resonator perturbation method (for example, using a tester that measures εr and tan δ for an ultra-thin sheet, manufactured by KEYCOM CORPORATION) according to a method described in Executive summaries of The 18^{th} Japan Institute of Electronics Packaging, Academic Lecture Meeting. p 189 (2004).

As mentioned above, it is also advantageous to select the insulating resin material from the viewpoint of dielectric constant or dielectric loss tangent. Examples of the insulating resin having a dielectric constant of 3.5 or less and a dielectric loss tangent of 0.01 or less include liquid crystal polymers, polyimide resins, fluorine resins, polyphenylene ether resins, cyanate ester resins, bis(bisphenylene)ethane resins, and modified resins of these resins.

The substrate for use in the invention preferably has a surface roughness of 500 nm or less, more preferably 100 nm or less, even more preferably 50 nm or less, and most preferably 20 nm or less, in view of applications to semiconductor packages, various electrical wiring boards, and the like. The smaller the surface roughness of the substrate (when an intermediate layer such as an adhesion-aiding layer is provided, the surface roughness of this layer), the less the electric loss at the time of transmitting electricity at high frequency can be made when the metal pattern material is used for wiring or the like. Accordingly, favorable results can be achieved by a relatively smaller surface roughness.

When the substrate is a plate-shaped material such as a resin film (plastic film), the layer to be plated can be formed on both sides of the substrate by conducting step (1) and then the below-described (2) to both sides of the substrate. When the layer to be plated is formed on both sides of the resin film (substrate) in the above manner, a metal pattern material in which a metal film is formed on the both sides can be obtained by further conducing steps (3) and (4) described below.

Adhesion-Aiding Layer

An adhesion-aiding layer may be provided on the substrate that is used for forming a pattern according to the invention. In the following, the adhesion-aiding layer according to the invention is described. If the substrate is a plate-shaped material, the adhesion-aiding layer may be formed on both sides of the substrate.

The adhesion-aiding layer according to the invention is an intermediate layer that secures adhesion between the substrate and the layer to be plated. This layer may have an affinity with the substrate and the layer to be plated, or may have an ability of forming chemical bonding upon reaction with the specific polymer during curing.

The adhesion-aiding layer is preferably formed from a resin composition having a favorable adhesion to the substrate, and a compound that generates radicals upon exposure with light. When the resin in the resin composition has a site that generates radicals, the compound that generates radicals may not be separately added.

When the substrate is formed from a known insulating resin that is used as a material for multilayer boards, build-up boards or flexible substrates, an insulating resin composition is preferably used as a resin composition that forms the adhesion-aiding layer, in view of adhesion to the substrate.

In the following, an embodiment in which the substrate is formed from an insulating resin and the adhesion-aiding layer is formed from an insulating resin composition is described.

The insulating resin composition that forms the adhesion-aiding layer may include the same insulating resin as the electrically insulating resin that forms the substrate, or may include a different insulating resin from the insulating resin that forms the substrate. However, the insulating resin composition that forms the adhesion-aiding layer preferably includes an insulating resin having similar thermal physical properties, such as the glass transition temperature, elastic modulus or linear coefficient of expansion, to those of the insulating resin that forms the substrate. Specifically, for example, the insulating resin that forms the adhesion-aiding layer is preferably the same kind as the insulating resin that forms the substrate in view of adhesion of the adhesion-aiding layer to the substrate.

The insulating resin composition may further include inorganic or organic particles, in order to improve the strength or electrical properties of the adhesion-aiding layer.

In the invention, the insulating resin used for the adhesion-aiding layer refers to a resin having an insulating property within a tolerable level for use in known insulating films. Therefore, even if a resin is not an absolute insulating material, the resin may be favorably used in the present invention, as long as it has insulating properties according to purposes.

Specific examples of the insulating resin include a thermosetting resin, thermoplastic resin or a combination of these resins.

Examples of the thermosetting resin include an epoxy resin, a phenol resin, a polyimide resin, a polyester resin, a bismaleimide resin, a polyolefin resin, and an isocyanate resin. Examples of the thermoplastic resin include a phenoxy resin, polyether sulfone, polysulfone, polyphenylene sulfone, polyphenylene sulfide, polyphenyl ether, polyether imide, an ABS resin, and a nitrile-butadiene rubber (NBR). These thermosetting resins and the thermoplastic resins may be used alone or in combination of two or more kinds

A resin having a skeleton that generates an active site capable of interacting with a plating catalyst-receptive photosensitive resin composition may be used as an insulating resin that is used in the adhesion-aiding layer. Examples of such a resin include a polyimide having a polymerization initiation site in its skeleton as described in paragraphs [0018] to of JP-A No. 2005-307140.

The adhesion-aiding layer according to the invention may include various kinds of compounds as long as the effects of the invention is not impaired.

Specific examples of such a compound include rubbers, substances such as SBR latex, binders for improving film properties, plasticizers, surfactants, and viscosity modifiers.

A composite (composition material) of a resin and other component(s) may also be used in the adhesion-aiding layer according to the invention, for the purpose of reinforcing the properties of the resin film such as mechanical strength, heat resistance, weather resistance, flame retardancy, water resistance or electrical properties. Examples of the material that may be used to form a composite include paper, glass fiber, silica particles, phenol resins, polyimide resins, bismaleimide triazine resins, fluorine resins, polyphenylene oxide resins, or the like.

Further, as necessary, one or more kinds of filler that are commonly used in a resin material for wiring boards may be incorporated in the adhesion-aiding layer. Examples of the filler include inorganic fillers such as silica, alumina, clay, talc, aluminum hydroxide and calcium carbonate, and organic fillers such as cured epoxy resin, crosslinked benzoguanamine resin and crosslinked acrylic polymer.

The adhesion-aiding layer may also include one or more additives of various kinds as necessary, such as a colorant, a flame retardant, a tackifier, a silane coupling agent, an antioxidant, an ultraviolet absorbent, or the like.

When such a material as described above is added to the adhesion-aiding layer, an addition amount of each material is in the range of preferably 0 to 200% by mass and more preferably 0 to 80% by mass, with respect to the amount of the resin as a main component. When the adhesion-aiding layer and the substrate that are adjacent to each other have the same or similar physical properties with respect to heat or electricity, these additives may not be added. When the above amount of the additive is more than 200% by mass, properties that are inherent to the resin, such as strength, may deteriorate.

The adhesion-aiding layer preferably includes, as mentioned above, a resin composition and a compound that generates radicals upon exposure with light.

In the invention, known photopolymerization initiators or light-sensitive resins can be used as the compound that generates radicals upon exposure with light.

Examples of the photopolymerization initiator include acetophenones such as p-tert-butyl trichloroacetophenone, 2,2′-diethoxyacetophenone, and 2-hydroxy-2-methyl-1-phenylpropan-1-one; ketones such as benzophenone, 4,4′-bisdimethylaminobenzophenone, 2-chlorothioxanthone, 2-methylthioxanthone, 2-ethylthioxanthone, and 2-isopropylthioxanthone; benzoin ethers such as benzoin, benzoin methyl ether, benzoin isopropyl ether, and benzoin isobutyl ether; benzyl ketals such as benzyl dimethyl ketal and hydroxycyclohexyl phenyl ketone; sulfonium salts such as triphenyl sulfonium chloride, triphenyl sulfonium pentafluoro phosphate; and iodonium salts such as diphenyl iodonium chloride and diphenyl iodonium sulfate.

The photopolymerization initiator (compound that generates radicals upon exposure with light) is incorporated in the adhesion-aiding layer preferably at an amount of from 0.1 to 50% by mass, and more preferably from 1.0 to 30% by mass, in terms of solid content.

The thickness of the adhesion-aiding layer according to the invention is generally from 0.1 to 10 μm, and preferably from 0.5 to 7 μm. When the adhesion-aiding layer has a thickness within this range, a sufficient level of adhesion to the adjacent substrate or the layer to be plated can be achieved. Further, a level of adhesion equivalent to that of a layer formed from a commonly used adhesive can be achieved, in spite of a thinner layer than the layer formed from the adhesive.

The surface of the adhesion-aiding layer according to the invention preferably has a surface roughness Rz of 3 μm or less, more preferably 1 μm or less, as measured in accordance with a ten-point average height method as stipulated by JIS B 0601 (1994), from the viewpoint of improving the properties of the plated metal film to be formed on the adhesion-aiding layer.

When a surface roughness of the adhesion-aiding layer is within the above range, namely the adhesion-aiding layer has a smooth surface, the adhesion-aiding layer can be favorably used in the production of a printing circuit board having an extremely fine circuit (for example, a circuit pattern having a line/space value of 25/25 μm or less).

The adhesion-aiding layer can be formed on the substrate by a known method such as a coating method, a transfer method or a printing method.

If desired, the adhesion-aiding layer may be patterned by a printing method (such as gravure printing, screen printing, flexographic printing, inkjet printing and imprint method), a development method (such as wet etching, dry etching, ablation, curing/plasticizing (negative/positive) with light), or the like.

The adhesion-aiding layer having been formed on the substrate may be subjected to a curing process by applying energy of some kind Examples of the energy to be applied include light, heat, pressure and electron beams, and heat or light is generally used in this embodiment. When energy is applied by heat, heating is preferably conducted at the temperature of from 100 to 300° C. for a period of from 5 to 120 minutes. The conditions for curing by heating may differ depending on the type of material for the substrate, the type of resin composition that forms the adhesion-aiding layer, or the curing temperatures of these materials, but are preferably selected from the temperature range of from 120 to 220° C. and the time range of from 20 to 120 minutes.

The curing treatment may be performed immediately after the formation of the adhesion-aiding layer. Alternatively, by conducting a pre-curing treatment for about 5 to about 10 minutes after the formation of the adhesion-aiding layer, the curing treatment can be performed after completion of all processes subsequent to the formation of the adhesion-aiding layer.

After formation of the adhesion-aiding layer, the surface of the same may be roughened by a dry or wet method in order to improve its adhesiveness with respect to the layer to be plated, which is to be formed on the adhesion-aiding layer. Examples of the dry roughening method include mechanical polishing such as buffing or sand blasting, and plasma etching. Examples of the wet roughening method include a chemical treatment using an oxidant such as permanganate, bichromate, ozone, hydrogen peroxide/sulfuric acid, or nitric acid; a strong base; or a resin-swelling solvent.

Step (2)

In step (2) of the method of producing a metal pattern material according to the invention, the uncured portion of the composition on the substrate is removed by developing with an aqueous solution to form a patterned layer to be plated.

Development with Aqueous Solution

Examples of the aqueous solution used in this step include an acidic aqueous solution, a neutral aqueous solution, and an alkali aqueous solution.

Examples of the acidic aqueous solution include an aqueous solution of hydrochloric acid, sulfuric acid or nitric acid.

Examples of the neutral aqueous solution include a surfactant that is dissolved in water. Anionic, nonionic or cationic surfactant may be used.

Of the aqueous solution, an alkali aqueous solution is preferable, and specific examples thereof include an aqueous solution of sodium hydroxide, potassium hydroxide, magnesium hydroxide, calcium hydroxide, sodium carbonate, potassium carbonate, magnesium carbonate, calcium carbonate, sodium hydrogen carbonate, potassium hydrogen carbonate, magnesium hydrogen carbonate and calcium hydrogen carbonate.

The concentration of the aqueous solution is generally from 0.01 to 10% by mass, and this can be determined according to the pKa value of the ionic polar group or the desired time for development.

The development can be performed by shower washing, immersion or the like. The development may also be performed by immersing the substrate in the development solution while stirring it.

The temperature for development is preferably selected from room temperature to 50° C., and the time for development is preferably selected from 5 seconds to 10 minutes.

Through the development process as mentioned above, a patterned layer to be plated is formed on the substrate. The thickness of the patterned layer to be plated is preferably from 0.2 to 1.5 μm, more preferably from 0.3 to 1.5 μm, and particularly preferably from 0.6 to 1.2 μm.

Step (3)

In step (3), a plating catalyst or a precursor thereof is applied to the layer to be plated that has been formed in the previous step (2).

In this step, the interactive group of the specific polymer that is included in the layer to be plated adheres (adsorbs) according to its function the applied plating catalyst or the precursor thereof.

Since the plating catalyst or the precursor thereof functions as a catalyst for plating or an electrode in the subsequent step (4), it is selected depending on the type of the plating to be performed in step (4).

In the invention, the plating catalyst or the precursor thereof used in this step is preferably an electroless plating catalyst or a precursor thereof.

Electroless Plating Catalyst

In the invention, the electroless plating catalyst may be any substance as long as it serves as an active nucleus during electroless plating. Examples thereof include metals having a catalytic ability of a self-catalytic reduction reaction. Specific examples include Pd, Ag, Cu, Ni, Al, Fe, Co and the like. Among them, those capable of multidentate coordination are preferred. From the viewpoints of the number of types of functional group capable of coordination and a high degree of catalytic ability, Ag and Pd are particularly preferred.

The electroless plating catalyst may be used in the form of a metal colloid. In general, a metal colloid may be produced by reducing metal ions in a solution including a charged surfactant or a charged protective agent. The electrical charge of the metal colloid can be controlled by the surfactant or protective agent included herein.

Electroless Plating Catalyst Precursor

The electroless plating catalyst precursor used in this step is not particularly limited, as long as it can act as an electroless plating catalyst through a chemical reaction. In general, metal ions of the metals as mentioned above as the electroless plating catalyst are used. A metal ion that serves as an electroless plating catalyst precursor becomes a zero-valent metal that serves as an electroless plating catalyst through a reduction reaction. The metal ion that serves as an electroless plating catalyst precursor may be reduced to a zero-valent metal to obtain an electroless plating catalyst by performing a separate reduction reaction, after applying the same to the layer to be plated and prior to immersing the substrate in an electroless plating bath; or may be reduced to a metal (electroless plating catalyst) during immersing the substrate in an electroless plating bath, using a reducing agent contained in the electroless plating bath.

In practical use, the metal ion (electroless plating catalyst precursor) is applied to the layer to be plated by using a metal salt. The metal salt is not particularly limited as long as it can dissolve in an appropriate solvent and dissociate into a metal ion and a base (anion). Specific examples thereof include M (NO₃)ₙ, M Clₙ, M_{2/n}(SO₄), M_{3/n}(PO₄) (M represents an n-valent metal atom). A dissociative form of the above-mentioned metal salts may be suitably used as the metal ion. Specific examples of the metal ion include an Ag ion, a Cu ion, an Al ion, a Ni ion, a Co ion, a Fe ion, and a Pd ion. Among them, those capable of multidentate coordination are preferred. From the viewpoints of the number of types of a functional group capable of coordination and the catalytic ability, an Ag ion and a Pd ion are particularly preferred.

In the invention, one preferable example of the electroless plating catalyst or the precursor thereof is a palladium compound. The palladium compound functions as a plating catalyst (palladium) or a plating catalyst precursor (palladium ion), which serves as an active nucleus and causes precipitation of a metal during plating. The palladium compound is not particularly limited as long as it includes palladium and functions as an active nucleus during plating, and examples thereof include a palladium (II) salt, a palladium (0) complex, and a palladium colloid.

Examples of the palladium salt include palladium acetate, palladium chloride, palladium nitrate, palladium bromate, palladium carbonate, palladium sulfate, bis(benzonitrile)dichloropalladium (II), bis(acetonitrile)dichloropalladium (II) and bis(ethylenediamine)palladium (II) chloride. Among these, palladium nitrate, palladium acetate, palladium sulfate and bis(acetonitrile)dichloropalladium (II) are preferred from the viewpoint of handleability and solubility.

Examples of the palladium complex include tetrakis(triphenylphosphine)palladium complex and tris(dibenzylideneacetone)dipalladium complex.

The palladium colloid is in the form of particles of palladium (0). The particle size is not particularly limited, and it is preferably from 5 to 300 nm, and more preferably from 10 to 100 nm, from the viewpoint of stability in a solution. If necessary, the palladium colloid may include a metal other than palladium, such as tin. One examples of the palladium colloid is a tin-palladium colloid. The palladium colloid may be prepared by a known method, or a commercially available product may be used. For example, the palladium colloid may be prepared by reducing palladium ions in a solution including a charged surfactant or a charged protection agent.

Another preferable examples of the electroless plating catalyst or the precursor thereof is silver or silver ions, from the viewpoint of being selectively adsorbed to the layer to be plated.

When the silver ions are used as the plating catalyst precursor, those obtained from dissociation of the following silver compounds are favorably used.

Specific examples of the silver compound include silver nitrate, silver acetate, silver sulfate, silver carbonate, silver cyanate, silver thiocyanate, silver chloride, silver bromate, silver chromate, silver chloranilate, silver salicylate, silver diethyldithiocarbamate, and silver p-toluenesulfonate. Among these, silver nitrate is preferred from the viewpoint of solubility in water.

The metal (electroless plating catalyst) or a metal salt (electroless plating catalyst precursor) can be applied to the layer to be plated by preparing a dispersion by dispersing the metal in a suitable medium, or preparing a solution including dissociated metal ions by dissolving the metal salt in a suitable solvent; and then applying the dispersion or the solution to the layer to be plated. Alternatively, the substrate with the layer to be plated formed thereon may be immersed in the dispersion or the solution.

It is also possible to add a plating catalyst or the precursor thereof to a composition for forming a layer to be plated, and then applying the composition to the substrate in step (1). Namely, a patterned layer to be plated including the plating catalyst or the precursor thereof can be formed on the substrate by contacting the composition including the specific polymer and the electroless plating catalyst or the precursor thereof to the substrate, and then by performing light exposure and development to the composition. In this way, steps (1) to (3) can be conducted in a single process.

When the substrate is a resin film and the layer to be plated is formed on both sides of the resin film, an immersion method as mentioned above is preferably used, so that the electroless plating catalyst or the precursor thereof can be contacted at the same time to the layers to be plated that are formed on both sides of the resin film.

By contacting the electroless plating catalyst or the precursor thereof to the layer to be plated as mentioned above, the electroless plating catalyst or the precursor thereof can be adsorbed to the interactive group in the layer to be plated by means of interaction due to an intermolecular force such as van der Waals' force or a coordination bond of lone-pair electrons.

From the viewpoint of achieving the above adsorption to a sufficient level, the concentration of metal in the dispersion, solution or composition, or the concentration of metal ions in the solution, is preferably from 0.001 to 50% by mass, and more preferably from 0.005 to 30% by mass.

The time for contacting is preferably from about 30 seconds to about 24 hours, and more preferably from about 1 minute to about 1 hour.

When a palladium compound is used in the solution, dispersion or composition that includes the electroless plating catalyst or the precursor thereof, the content of the palladium compound is preferably from 0.001 to 10% by mass, more preferably from 0.005 to 5% by mass, and yet more preferably from 0.1 to 1% by mass, with respect to a total amount of the solution, dispersion or composition.

When a silver compound is used in the solution, dispersion or composition that includes the electroless plating catalyst or the precursor thereof, the content of the silver compound is preferably from 0.1 to 20% by mass, more preferably from 0.1 to 20% by mass, and yet more preferably from 0.5 to 10% by mass, with respect to a total amount of the solution, dispersion or composition.

In either of the above two cases, when the content of the metal compound is too small, precipitation in the subsequent plating may not easily occur, and when the content of the meal compound is too large, precipitation may occur in an undesired portion, or removability of etching residues may become impaired.

The amount of the electroless plating catalyst or the precursor thereof to be adsorbed may differ depending on the type of electroless plating catalyst or precursor thereof.

The amount of silver ions to be adsorbed to the layer to be plated is preferably 300 mg/m² or more, more preferably 500 mg/m² or more, and yet more preferably 600 mg/m² or more, from the viewpoint of performing satisfactory precipitation in the electroless plating. From the viewpoint of forming a metal pattern that is highly adhesive to the substrate, the amount of silver ions to be adsorbed is preferably 1000 mg/m² or less.

The amount of palladium ions to be adsorbed to the layer to be plated is preferably 5 mg/m² or more, and more preferably 10 mg/m² or more, from the viewpoint of performing satisfactory precipitation in the electroless plating. From the viewpoint of forming a metal pattern that is highly adhesive to the substrate, the amount of palladium ions to be adsorbed is preferably 1000 mg/m² or less.

Other Catalysts

In the invention, when electroplating is directly conducted in the subsequent step (4) without performing electroless plating, a zero-valent metal may be used as the catalyst for the electroplating. Examples of the zero-valent metal include Pd, Ag, Cu, Ni, Al, Fe and Co. Among these, those capable of multidentate coordination are preferable, and Pd, Ag and Cu are particularly preferred in view of adsorbability (attachability) to the interactive group (such as a cyano group).

Organic Solvent and Water

The plating catalyst or the precursor thereof can be applied in the form of a dispersion or a solution (catalyst solution), as mentioned above.

In the invention, an organic solvent or water can be used for the catalyst solution.

By including the organic solvent, permeability of the layer to be plated with respect to the plating catalyst or the precursor thereof can be improved, and the plating catalyst or the precursor thereof can be adsorbed to the interactive group in the layer to be plated with high efficiency.

Water may be used in the catalyst solution according to the invention. The water preferably includes no impurities. From this point of view, RO water, deionized water, distilled water and purified water are preferred, and deionized water and distilled water are particularly preferred.

The organic solvent for use in preparing the catalyst solution is not particularly limited as long as it can penetrate into the layer to be plated. Specific examples thereof include acetone, methyl acetoacetate, ethyl acetoacetate, ethylene glycol diacetate, cyclohexanone, acetylacetone, acetophenone, 2-(1-cyclohexenyl)cyclohexanone, propylene glycol diacetate, triacetine, diethylene glycol diacetate, dioxane, N-methyl pyrrolidone, dimethyl carbonate, and dimethyl cellosolve.

Other examples of the organic solvent include diacetone alcohol, γ-butyrolactone, methanol, ethanol, isopropyl alcohol, n-propyl alcohol, propylene glycol monomethyl ether, methyl cellosolve, ethyl cellosolve, ethylene glycol tertiary butyl ether, tetrahydrofuran, 1,4-dioxane, n-methyl-2-pyrrolidone, triethylene glycol monomethyl ether, diethylene glycol dimethyl ether, and diethylene glycol diethyl ether.

From the viewpoint of compatibility with the plating catalyst or the precursor thereof, or organic solvent permeability of the layer to be plated, acetone, dimethyl carbonate, dimethyl cellosolve, triethylene glycol monomethyl ether, diethylene glycol dimethyl ether and diethylene glycol diethyl ether are particularly preferred.

The catalyst solution according to the invention may include other additives according to the intended use. Examples of the other additives include a swelling agent (e.g., organic compounds such as ketones, aldehydes, ethers and esters) and a surfactant (e.g., anionic, cationic, amphoteric, nonionic, low-molecular or high-molecular surfactants).

Via the step (3) as mentioned above, interaction can be formed between the interactive group in the layer to be plated and the plating catalyst or the precursor thereof.

Step (4)

In step (4) of the method of producing a metal pattern material according to the invention, a plated film is formed by performing plating with respect to the layer to be plated to which the electroless plating catalyst or the precursor thereof has been applied. The obtained plated film may exhibit excellent conductivity and adhesivenenss.

The type of plating to be performed in this step may be electroless plating, electroplating or the like, which can be selected according to the function of the plating catalyst or the precursor thereof that has completed interaction with the layer to be plated in the above-described step (3).

Namely, in this step, either electroplating or electroless plating may be performed with respect to the layer to be plated to which the electroless plating catalyst or the precursor thereof has been applied.

Among these, in the invention, electroless plating is preferably performed from the viewpoint of forming a hybrid structure that occurs in the layer to be plated, or improving the adhesion between the layer to be plated and the resultant plated layer. In a more preferred embodiment, electroplating is performed subsequent to the electroless plating so as to form a plated layer with a desired thickness.

In the following, a preferred embodiment of the plating is described.

Electroless Plating

Electroless plating is an operation of precipitating a metal by means of a chemical reaction, using a solution in which ions of the metal to be precipitated are dissolved.

The electroless plating in this step is carried out by, for example, washing the substrate to which the electroless plating catalyst has been applied with water to remove an excessive amount of electroless plating catalyst (metal), and then immersing the substrate in an electroless plating bath. A generally known electroless plating bath can be used in this process.

In the case in which the substrate provided thereon with the layer to be plated to which an electroless plating catalyst precursor has been applied is immersed in the electroless plating bath in such a state that the electroless plating catalyst precursor is adsorbed to (or impregnated in) the layer to be plated, the substrate is washed with water to remove an excessive amount of the precursor (metal salt or the like) and then the resultant substrate is immersed in the electroless plating bath. In this case, reduction of the plating catalyst precursor and the subsequent electroless plating are carried out in the electroless plating bath. A generally known electroless plating bath may be used in this case, too.

Apart from the abovementioned embodiment in which an electroless plating bath is used, the reduction of the electroless plating catalyst precursor may be carried out in a separate process prior to the electroless plating, by using a catalyst activating solution (reducing solution). The catalyst activating solution is a solution in which a reducing agent that reduces the electroless plating catalyst precursor (typically metal ions) to a zero-valent metal is dissolved, and the concentration of the reducing agent is generally in the range of from 0.1 to 50% by mass, and preferably in the range of from 1 to 30% by mass. Examples of the reducing agent that may be used include boron-based reducing agents such as sodium borohydride and dimethylamine borane, and reducing agents such as formaldehyde and hypophosphorous acid.

When immersion is performed, it is preferable to immerse the substrate provided thereon with the layer to be plated into a solution while stirring or shaking in order to maintain a constant level of an electroless plating catalyst or the precursor thereof near the surface of the layer to be plated, that contacts with the electroless plating catalyst or the precursor thereof.

The electroless plating bath typically includes, as main components in addition to a solvent, (1) metal ions for the plating, (2) a reducing agent, and (3) an additive (stabilizer) that enhances the stability of the metal ions. The electroless plating bath may further include a known additive such as a stabilizer for the plating bath, in addition to the above components.

The organic solvent used in the plating bath should be soluble in water. From this point of view, ketones such as acetone or alcohols such as methanol ethanol or isopropanol are preferably used.

Examples of the metal used in the electroless plating bath include copper, tin, lead, nickel, gold, palladium and rhodium. From the viewpoint of electrical conductivity, copper and gold are preferred.

The optimal reducing agent and additive may be selected in combination with the metal to be used. For example, the electroless plating bath of copper contains CuSO₄ as a copper salt, HCOH as a reducing agent, and, as another additive, a chelating agent that serves as a stabilizer of copper ions such as EDTA or Rochelle salt, and trialkanolamine or the like. The electroless plating bath of CoNiP contains cobalt sulfate or nickel sulfate as a metal salt, sodium hypophosphite as a reducing agent, and sodium malonate, sodium malate or sodium succinate as a complexing agent. The electroless plating bath of palladium contains (Pd(NH₃)₄)Cl₂ as a metal ion, NH₃ or H₂NNH₂ as a reducing agent, and EDTA as a stabilizer. These plating baths may also contain other components than the above-described components.

The thickness of the plated film formed by the electroless plating may be controlled by adjusting the concentration of the metal ion in the plating bath, the immersion time in the plating bath, the temperature of the plating bath, or the like. From the viewpoint of electroconductivity, the thickness of the plated film is preferably from 0.1 μm or more, and more preferably from 0.2 to 2 μm.

In this regard, when electroplating is performed using the plated film formed by the electroless plating as a conduction layer, the plated film needs to have a thickness of at least 0.1 μm in a uniform manner.

The immersion time in the plating bath is preferably from 1 minute to about 6 hours, more preferably from 1 minute to about 3 hours.

When the plated film thus obtained by the electroless plating is observed at a cross-section with a scanning electron microscope (SEM), it is found that electroless plating catalyst or plated metal microparticles are dispersed in the layer to be plated at high density, and that further the plated metal has precipitated on the layer to be plated. Since the interface between the layer to be plated and the plated layer is in a hybrid state of a resin composite and the microparticles, favorable adhesiveness can be achieved even when the interface between the layer to be plated (organic component) and the inorganic substance (plating catalyst metal or plated metal) is flat and smooth (for example, Ra is 1.5 μm or less at an area of 1 mm²).

Electroplating

In this step, if the plating catalyst or the precursor thereof that has been applied in the precedent step (3) functions as an electrode, electroplating can be performed with respect to the layer to be plated to which the catalyst or the precursor thereof has been applied.

It is also possible to perform electroplating subsequent to the above-described electroless plating, by using, as an electrode, a plated film that has been formed in the electroless plating. In this way, a metal film having a desired thickness can be further readily formed on a base of the electroless plated film that is closely adhered to the substrate. Accordingly, electroplating subsequent to the electroless plating makes it possible to form a metal film having a desired thickness in accordance with the intended use. As a result, the thus-obtained metal film can be favorably used for various applications.

The electroplating according to the invention can be performed by a conventionally known method. Examples of the metal that may be used in the electroplating include copper, chromium, lead, nickel, gold, silver, tin, and zinc. From the viewpoint of electrical conductivity, copper, gold and silver are preferred and copper is more preferred.

A thickness of the metal film obtained by the electroplating can be controlled by adjusting the concentration of the metal contained in the plating bath, current density, or the like.

In the case of applying the thus-obtained metal pattern material to a commonly used-electrical wiring or the like, the film thickness of a metal film is preferably 0.5 μm or more, and more preferably from 1 to 30 μm, from the viewpoint of electrical conductivity.

In this regard, the narrower (finer) the width of the electrical wiring is, the thinner the thickness of the electrical wiring needs to be so as to maintain a certain aspect ratio. Therefore, a thickness of the plated film formed in the electroplating can be arbitrarily determined without being limited to the above range.

Examples of other production method of the plated film include a method of preliminarily mixing a plating catalyst or the precursor thereof in a composition for forming a layer to be plated, and then forming the layer to be plated from this composition on a substrate by the aforementioned method of coating, extrusion molding, laminating or the like.

In this case, since the layer to be plated that includes the plating catalyst or the precursor thereof is prepared by one step without performing the above-described step (c), this method is preferable from the viewpoint of operation efficiency and productivity.

Metal Pattern Material

The metal pattern material of the invention can be obtained through the aforementioned steps of the method of producing a metal pattern material of the invention.

According to this method, by using a resin film or the like as the substrate, a metal pattern material having a metal pattern on both sides of the resin film can be obtained. The metal pattern material of the invention includes a metal pattern having excellent adhesion to the substrate.

The metal pattern material of the invention preferably has a plated film that is formed on portions of a substrate surface having a roughness of 500 nm or less (more preferably 100 nm or less). Further, the metal pattern material preferably exhibits an adhesion between the substrate and the metal pattern of 10 or less in 100 squares, as measured by a cross cut test stipulated by JIS-K5600. Namely, the metal pattern material of the invention achieves excellent adhesion between the substrate and the metal pattern even when the substrate has a smooth surface.

The aforementioned value of surface roughness of the substrate is measured by cutting the substrate in a vertical manner to the substrate surface, and then observing a cross section of the substrate with an SEM.

More specifically, the above value of surface roughness refers to Rz as measured in accordance with JIS B0601. Namely, the above value of surface roughness is preferably 500 nm or less in terms of the difference between the average value of Z data measured at peaks of from first to fifth highest points and the average value of Z data measured at valleys of from first to fifth lowest points.

The metal pattern material obtained by the method of producing a metal pattern material of the invention can be used in various applications such as semiconductor chips, various electric circuit boards, FPCs, COFs, TABs, antennas, multilayer wiring substrates, and mother boards.

The following are exemplary embodiment of the invention. However, the invention is not limited thereto.
(1) A composition for forming a layer to be plated, the composition including a solution in which from 1% by mass to 20% by mass of a polymer having a functional group that forms an interaction with a plating catalyst or a precursor thereof and a radical polymerizable group, and a water-insoluble photopolymerization initiator are dissolved in a mixed solvent including from 20% by mass to 99% by mass of a water-soluble flammable liquid and water.
(2) The composition for forming a layer to be plated according to (1), wherein the water-insoluble photopolymerization initiator is included in the range of from 1% by mass to 20% by mass with respect to the polymer having a functional group that forms an interaction with a plating catalyst or a precursor thereof and a radical polymerizable group.
(3) The composition for forming a layer to be plated according to (1) or (2), wherein the water-soluble flammable liquid includes an alcohol-based solvent.
(4) The composition for forming a layer to be plated according to any one of (1) to (3), wherein the water-insoluble photopolymerization initiator includes a compound having an absorbance peak in the range of from 250 nm to 400 nm.
(5) The composition for forming a layer to be plated according to any one of (1) to (4), wherein, in the polymer having a functional group that forms an interaction with a plating catalyst or a precursor thereof and a radical polymerizable group, the functional group that forms an interaction with a plating catalyst or a precursor thereof includes a non-dissociative functional group or an ionic polar group that forms an interaction with a plating catalyst or a precursor thereof.
(6) The composition for forming a layer to be plated according to (5), wherein the non-dissociative functional group includes an ether group, or a cyano group.
(7) The composition for forming a layer to be plated according to (5), wherein the ionic polar group includes a carboxylic acid group.
(8) The composition for forming a layer to be plated according to claim 1, wherein the radical polymerizable group includes an acryloyl group, a methacryloyl group, an acrylamide group, a methacrylamide group, an allyl group, a vinyl group, or a styryl group.
(9) The composition for forming a layer to be plated according to claim 1, wherein the polymer having a functional group that forms an interaction with a plating catalyst or a precursor thereof and a radical polymerizable group includes a copolymer which comprises a unit represented by the above-described Formula (A) and a unit represented by the above-described Formula (B).
(10) The composition for forming a layer to be plated according to claim 9, wherein the unit represented by Formula (B) includes an alicyclic carboxylic group at a terminal of the unit.
(11) The composition for forming a layer to be plated according to claim 9, wherein, in Formula (B), W is a carboxylic acid group, and a chain length of L² is in the range of from 6 atoms to 18 atoms.
(12) The composition for forming a layer to be plated according to (9), wherein, in Formula (B), W is a carboxylic acid group, and both X and L² are each a single bond.
(13) The composition for forming a layer to be plated according to (9), wherein the value of ionic polarity or an acid value of the unit represented by Formula (B) is in the range of from 1.5 mmol/g to 10.0 mmol/g.
(14) The composition for forming a layer to be plated according to (9), wherein the polymer having a functional group that forms an interaction with a plating catalyst or a precursor thereof and a radical polymerizable group comprises a copolymer further comprising a unit represented by the above-described Formula (C).
(15) The composition for forming a layer to be plated according to any one of (1) to (14), wherein the content of the water-soluble flammable liquid in the mixed solvent is in the range of from 30% by mass to 80% by mass.
(16) The composition for forming a layer to be plated according to (7), wherein the composition further includes an additive selected from the group consisting of sodium hydrogen carbonate, sodium carbonate and sodium hydroxide.
(17) The composition for forming a layer to be plated according to any one of (1) to (16), wherein the water-insoluble photopolymerization initiator includes a benzoin compound or a derivative thereof a benzyl ketal-based compound or a derivative thereof a hydroxy ketone-based compound or a derivative thereof a benzophenone-based compound or a derivative thereof an acetophenone-based compound or a derivative thereof an α-aminoalkyl phenone-based compound or a derivative thereof a bisacyl phosphinoxide-based compound or a derivative thereof an acyl phosphinoxide-based compound or a derivative thereof a thioxanthone-based compound or a derivatives thereof an anthraquinone-based compound or a derivative thereof; or an oxime ester-based compound or a derivative thereof.
(18) A method of producing a metal pattern material including:

coating the composition for forming a layer to be plated according to claim 1 on or above a substrate or an adhesion-aiding layer to form a coated film for forming a layer to be plated, and then applying energy to the coated film for forming a layer to be plated and curing the coated film at a portion to which the energy has been applied;

forming a patterned layer by developing an uncured portion of the coated film on or above the substrate or the adhesion-aiding layer with an aqueous solution;

applying a plating catalyst or a precursor thereof to the patterned layer; and

plating the plating catalyst or the precursor thereof.
(19) A method of producing a metal pattern material according to (18), wherein the application of energy is carried out by exposure to light having a wavelength of from 250 nm to 400 nm, and preferably 280 nm to 370 nm.
(20) A metal pattern material produced by the method according to (18) or (19).

### EXAMPLES

In the following, details of the invention will be explained with reference to the Examines. However, the invention is not limited thereto. The terms “%” and “parts” are based on mass, unless otherwise specified.

### Example 1

Production of Substrate

A mixed solution, in which 12.3 mass parts of JER806 (bisphenol F-type epoxy resin: trade name, manufactured by Japan Epoxy Resins Co., Ltd.), 4.3 mass parts of LA7052 (PHENOLITE, trade name, manufactured by DIC Corporation, hardener), 20.9 mass parts of YP50-35EK (trade name, manufactured by Tohto Kasei Co., Ltd., phenoxy resin), 62.5 mass parts of cyclohexanone and 0.1 mass parts of 2-ethyl-4-methylimidazole (hardening accelerator) were mixed, was filtrated with a filter cloth (mesh #200). The thus-prepared coating liquid was coated on a glass epoxy substrate so as to be an adhesion-aiding layer according to a spin coat method (condition: dry film thickness of 6 μm), and then dried thereby obtaining substrate A1.

### Synthesis Example 1

### Synthesis of Specific Polymer A

20 g of N,N-dimethylacetoamide were placed in a 500 ml three-neck flask, and were heated to 65° C. under a nitrogen stream. Then, 20.7 g of monomer M (following structure), 20.5 g of 2-cyanoethyl acrylate (manufactured by TOKYO CHEMICAL INDUSTRY CO., LTD.), 14.4 g of acryclic acid (manufactured by TOKYO CHEMICAL INDUSTRY CO., LTD), and 20 g of a N,N-dimethylaceamide solution containing 1.0 g of V-65 (trade name, manufactured by WAKO PURE CHEMICAL INDUSTRIES, LTD.) were dropped in the flask over 4 hours. After the dropping, the content of the flask was stirred for 3 hours. Thereafter, 91 g of N-N-dimethylacetoamide were added to the flask and the reaction solution was cooled to room temperature.

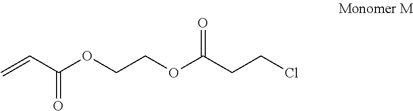

To the above reaction solution, 0.17 g of 4-hydroxy TEMPO (manufactured by TOKYO CHEMICAL INDUSTRY CO., LTD.) and 75.9 g of triethylamine were added and allowed to react at room temperature for 4 hours. Thereafter, 112 g of a 70% aqueous solution of methane sulfonic acid were added to the reaction solution. After the reaction, the reaction solution was subjected to re-precipitation with water and a solid was recovered. 25 g of specific polymer A having the following structure were obtained. The acid value of specific polymer A was 4.0 mmol/g.

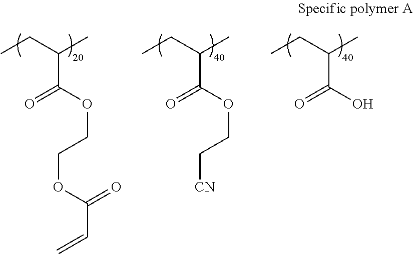

Preparation of Composition A for Forming a Layer to be Plated

0.30 g (7.5% by mass) of the specific polymer A (the above-described structure; weight average molecular weight: 44,000; solid content: 87% by mass), 0.07 g (1.75% by mass) of sodium hydrogen carbonate, and 1.63 g (40.6% by mass) of water were mixed while stirring to dissolve the specific polymer A, and then 2.0 g (49.9% by mass) of methanol and 0.01 g (0.25% by mass) of water-insoluble photopolymerization initiator (IRGACURE 907, trade name, Chiba Japan K.K.) were added thereto and stirred to prepare a composition A for forming a layer to be plated. At this time, the content of methanol contained in the water-alcohol mixed solvent was 55.1% by mass. Further, after the production of the composition A for forming a layer to be plated and subsequent leaving thereof to stand for 10 minutes, occurrence of precipitation was not seen by visual observation.

Formation of Layer to be Plated

The thus-prepared composition A for forming a layer to be plated was applied onto the adhesion-aiding layer of the above-described substrate A1 so as to be a thickness of 1 μm according to a spin coat method, and was dried at 80° C. for 30 minutes.

Then, pattern exposure to the coated film of the composition for forming a layer to be plated was carried out through a photomask having line-and-space of 300 μm with exposure energy of 100 mJ to 8,000 mJ using a UV exposure machine (wavelength: 365 nm (wavelength cutting at short wavelength side using soda glass), Model No: UVF-502S, lamp: UXM-501MD, all trade names, manufactured by SAN-EI ELECTRIC CO., LTD.).

After the exposure, the substrate was immersed in a 1% NaHCo₃ aqueous solution for 10 minutes, and was then washed with distilled water.

Substrate A2 having a patterned layer to be plated was thus obtained.

Application of Plating Catalyst

Substrate A2 with a layer to be plated was immersed in a 1% by mass silver nitrate aqueous solution for 10 minutes, and was then immersed in water for washing.

Patterned Electroless Plating

Substrate A2 with a patterned layer to be plated onto which a plating catalyst had been applied was subjected to electroless plating at 30° C. for 30 minutes, using an electroless plating bath having the following composition thereby obtaining a metal pattern material. The thickness of the obtained electroless plating film was 1 μm.

### Composition of Electroless Plating Bath

| | |
|---|---|
| Distilled water | 463 g |
| OPC COPPER T1 (manufactured by OKUNO CHEMICAL | 33 g |
| INDUSTRIES CO., LTD) | |
| OPC COPPER T3 (manufactured by OKUNO CHEMICAL | 55 g |
| INDUSTRIES CO., LTD) | |
| Formalin | 5.35 g |

Entire Surface Electroless Plating

In order to evaluate adhesion, by use of the composition A for forming a layer to be plated and exposure without a photomask, a composition layer to be plated was formed on the entire surface of the substrate, and a plated film having a thickness of 0.1 μm to 1.5 μm was produced as described below.

### Composition of Electroless Plating Bath

| | | |
|---|---|---|
| Distilled water | 774 | g |
| ATS ADCOPPER IW-A | 45 | mL |
| (trade name, manufactured by OKUNO CHEMICAL | | |
| INDUSTRIES, CO., LTD.) | | |
| ATS ADCOPPER IW-M | 72 | mL |
| (trade name, manufactured by OKUNO CHEMICAL | | |
| INDUSTRIES, CO., LTD.) | | |
| ATS ADCOPPER IW-C | 9 | mL |
| (trade name, manufactured by OKUNO CHEMICAL | | |
| INDUSTRIES, CO., LTD.) | | |
| NaOH | 1.98 | g |
| 2,2′-bipyridyl | 1.8 | mg |

All Over Electroplating

Subsequently, electroplating was performed in a copper electroplating bath having the following composition at 3 A/dm² for 20 minutes, using the copper electroless plating film as a feed layer. The thickness of the obtained copper electroplating film was 18 μm.

Composition of Electroplating Bath

| | | |
|---|---|---|
| Copper sulfate | 38 | g |
| Sulfuric acid | 95 | g |
| Hydrochloric acid | 1 | mL |
| COPPER GLEAM (manufactured by MELTEX INC.) | 3 | mL |
| Water | 500 | g |

### Example 2

Preparation of Composition B for Forming a Layer to be Plated

0.30 g (7.5% by mass) of the specific polymer A (solid content: 87% by mass) obtained by the synthesis method described above, 0.07 g (1.75% by mass) of sodium hydrogen carbonate, 1.63 g (40.6% by mass) of water and 2.0 g (49.9% by mass) of ethanol were mixed while stirring to dissolve the specific polymer A, and then 0.01 g (0.25% by mass) of water-insoluble photopolymerization initiator (IRGACURE 907, trade name, manufactured by CIBA JAPAN K.K.) were added thereto and stirred to prepare a composition B for forming a layer to be plated. At this time, the content of ethanol contained in the water-alcohol mixed solvent was 55.1% by mass. Further, after the production of the composition B for forming a layer to be plated and subsequent leaving to stand for 10 minutes, occurrence of precipitation was not found by visual observation.

A metal pattern material having a copper plating film was obtained in the same manner as Example 1 except that the composition A for forming a layer to be plated, used in Example 1, was changed to the composition B for forming a layer to be plated that was obtained above.

### Example 3

Preparation of Composition C for Forming a Layer to be Plated

0.30 g (7.5% by mass) of the specific polymer A (solid content: 87% by mass) obtained by the synthesis method described above, 0.07 g (1.75% by mass) of sodium hydrogen carbonate, and 1.63 g (40.6% by mass) of water were mixed while stirring to dissolve the specific polymer A, and then 2.0 g (49.9% by mass) of methanol and 0.01 g (0.25% by mass) of water-insoluble photopolymerization initiator (IRGACURE 379, trade name, manufactured by CIBA JAPAN K.K.) were added thereto and stirred to prepare a composition C for forming a layer to be plated. At this time, the content of methanol contained in the water-alcohol mixed solvent was 55.1% by mass. Further, after the production of the composition C for forming a layer to be plated and subsequent leaving thereof to stand for 10 minutes, occurrence of precipitation was not seen by visual observation.

A metal pattern material having a copper plating film was obtained in the same manner as Example 1 except that the composition A for forming a layer to be plated, used in Example 1, was changed to the composition C for forming a layer to be plated that was obtained above.

### Example 4

Preparation of Composition D for Forming a Layer to be Plated

0.30 g (7.5% by mass) of the specific polymer A (solid content: 87% by mass) obtained by the synthesis method described above, 0.07 g (1.75% by mass) of sodium hydrogen carbonate, and 1.63 g (40.6% by mass) of water were mixed while stirring to dissolve the specific polymer A, and then 2.0 g (49.9% by mass) of methanol and 0.01 g (0.25% by mass) of water-insoluble photopolymerization initiator (OXE-2, trade name, manufactured by CIBA JAPAN K.K.) were added thereto and stirred to prepare a composition D for forming a layer to be plated. At this time, the content of methanol contained in the water-alcohol mixed solvent was 55.1% by mass. Further, after the production of the composition D for forming a layer to be plated and subsequent leaving thereof to stand for 10 minutes, occurrence of precipitation was not seen by visual observation.

A metal pattern material having a copper plating film was obtained in the same manner as Example 1 except that the composition A for forming a layer to be plated, used in Example 1, was changed to the composition D for forming a layer to be plated that was obtained above.

### Example 5

### Synthesis Example 2

### Synthesis of the Specific Polymer B

200 g of N,N-dimethyl acetamide, 30 g of polyacrylic acid, 2.4 g of tetraethyl ammonium benzyl chloride, 25 mg of di-tert-pentylhydroquinone and 27 g of the following monomer B were placed in a 500 mL three neck flask, and reacted under nitrogen air flow at 100° C. for 5 hours.

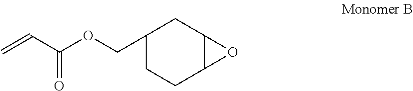

Then, 50 g of reaction liquid was taken, 11.6 mL of 4N NaOH was added thereto in an ice bath, followed by reprecipitation with ethyl acetate, solids were collected by filtration, then washed with water and dried, thereby obtaining 3.1 g of the specific polymer B (solid content: 99% by mass, weight average molecular weight: 16,000) having the following structure.

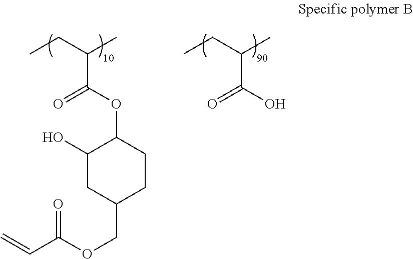

Preparation of Composition E for Forming a Layer to be Plated

0.36 g (7.2% by mass) of the specific polymer B (solid content: 99% by mass) obtained by the synthesis method described above, 0.19 g (3.83% by mass) of sodium hydrogen carbonate, and 1.75 g (35.3% by mass) of water were mixed while stirring to dissolve the specific polymer B, and then 2.66 g (53.6% by mass) of methanol and 0.018 g (0.36% by mass) of water-insoluble photopolymerization initiator (IRGACURE 907, trade name, manufactured by CIBA JAPAN K.K.) were added thereto and stirred to prepare a composition E for forming a layer to be plated. At this time, the content of methanol contained in the water-alcohol mixed solvent was 53.6% by mass. Further, after the production of the composition E for forming a layer to be plated and subsequent leaving thereof to stand for 10 minutes, occurrence of precipitation was not seen by visual observation.

A metal pattern material having a copper plating film was obtained in the same manner as Example 1 except that the composition A for forming a layer to be plated, used in Example 1, was changed to the composition E for forming a layer to be plated that was obtained above.

### Example 6

### Preparation of Composition F for Forming a Layer to be Plated

1.40 g (10.05% by mass) of the specific polymer A (solid content: 79% by mass) obtained by the synthesis method described above, 0.338 g (2.42% by mass) of sodium hydrogen carbonate, and 2.42 g (17.35% by mass) of water were mixed and stirred to dissolve the specific polymer A, and then 9.67 g (69.39% by mass) of 1-methoxy-2-propanol and 0.11 g (0.79% by mass) of water-insoluble photopolymerization initiator (OXE-2, trade name, manufactured by CIBA JAPAN K.K.) were added thereto and stirred to prepare a composition F for forming a layer to be plated. At this time, the content of 1-methoxy-2-propanol contained in the water-alcohol mixed solvent was 80.0% by mass. Further, after the production of the composition F for forming a layer to be plated and subsequent leaving thereof to stand for 10 minutes, occurrence of precipitation was not seen by visual observation.

Formation of Layer to be Plated

Further, the prepared composition F for forming a layer to be plated was coated by spin coating method so as to have a thickness of 1 μm on an adhesion-aiding layer of the substrate A1, followed by drying at 120° C. for 30 minutes.

Then, pattern exposure to the coated film of the composition for forming a layer to be plated was carried out through a photomask having line-and-space of 300 μm with exposure energy of 100 mJ to 8,000 mJ using a UV exposure machine (wavelength: 365 nm (wavelength cutting at short wavelength side using soda glass), Model No: UVF-502S, lamp: UXM-501MD, all trade names, manufactured by SAN-EI ELECTRIC CO., LTD.).

The substrate after exposure was immersed in a 1% by mass of aqueous NaHCO₃ solution for 10 minutes, followed by washing with distilled water.

A metal pattern material having a copper plated film was obtained by subjecting the obtained layer to be plated to the same process following catalyst application as in Example 1.

### Example 7

Preparation of Composition G for Forming a Layer to be Plated

0.20 g (7.80% by mass) of the specific polymer A (solid content:82% by mass) obtained by the synthesis method described above, 0.06 g (2.23% by mass) of sodium hydrogen carbonate, and 0.92 g (35.89% by mass) of water were mixed while stirring to dissolve the specific polymer A, and then 1.37 g (53.44% by mass) of 1-methoxy-2-propanol and 0.016 g (0.64% by mass) of water-insoluble photopolymerization initiator (IRGACURE 379, trade name, manufactured by CIBA JAPAN K.K.) were added thereto and stirred to prepare a composition G for forming a layer to be plated. At this time, the content of 1-methoxy-2-propanol contained in the water-alcohol mixed solvent was 59.8% by mass. Further, after the production of the composition G for forming a layer to be plated and subsequent leaving thereof to stand for 10 minutes, occurrence of precipitation was not seen by visual observation.

A metal pattern material having a copper plated film was obtained in the same manner as Example 6 except that the composition F for forming a layer to be plated, used in Example 6, was changed to the above obtained composition G for forming a layer to be plated.

### Example 8

Preparation of Composition H for Forming a Layer to be Plated

0.20 g (7.80% by mass) of the specific polymer A (solid content: 82% by mass) obtained by the synthesis method described above, 0.06 g (2.23% by mass) of sodium hydrogen carbonate, and 0.92 g (35.89% by mass) of water were mixed while stirring to dissolve the specific polymer A, and then 1.37 g (53.44% by mass) of methyl lactate and 0.016 g (0.64% by mass) of water-insoluble photopolymerization initiator (IRGACURE 379, trade name, manufactured by CIBA JAPAN K.K.) were added thereto and stirred to prepare a composition H for forming a layer to be plated. At this time, the content of methyl lactate contained in the water-water-soluble flammable liquid mixed solvent was 59.8% by mass. Further, after the production of the composition H for forming a layer to be plated and subsequent leaving thereof to stand for 10 minutes, occurrence of precipitation was not seen by visual observation.

A metal pattern material having a copper plated film was obtained in the same manner as Example 6 except that the composition F for forming a layer to be plated, used in Example 6, was changed to the above obtained composition H for forming a layer to be plated.

### Example 9

Preparation of Composition I for Forming a Layer to be Plated

0.20 g (7.80% by mass) of the specific polymer A (solid content: 82% by mass) obtained by the synthesis method described above, 0.06 g (2.23% by mass) of sodium hydrogen carbonate, and 0.92 g (35.89% by mass) of water were mixed while stirring to the specific polymer A, and then 1.37 g (53.44% by mass) of N-ethyl morpholine and 0.016 g (0.64% by mass) of water-insoluble photopolymerization initiator (IRGACURE 379, trade name, manufactured by CIBA JAPAN K.K.) were added thereto and stirred to prepare a composition I for forming a layer to be plated. At this time, the content of N-ethyl morpholine contained in the water-water-soluble flammable liquid mixed solvent was 59.8% by mass. Further, after the production of the composition I for forming a layer to be plated and subsequent leaving thereof to stand for 10 minutes, occurrence of precipitation was not seen by visual observation.

A metal pattern material having a copper plated film was obtained in the same manner as Example 6 except that the composition F for forming a layer to be plated, used in Example 6, was changed to the above obtained composition I for forming a layer to be plated.

### Comparative Example 1

Preparation of Composition J for Forming a Layer to be Plated

0.70 g (6.97% by mass) of the specific polymer A (solid content:87% by mass), 8.56 g (85.24% by mass) of water and 0.24 g (2.39% by mass) of sodium hydrogen carbonate were mixed and stirred to prepare a solution containing the specific polymer A dissolved therein. Separately, 0.5 g (4.98% by mass) of methanol, 0.021 g (0.21% by mass) of water-insoluble photopolymerization initiator (IRGACURE 907 used in Example 1) and 0.021 g (0.21% by mass) of surfactant (Aqalon RN-20, trade name, manufactured by DAI-ICHI KOGYO SEIYAKU CO., LTD.) were mixed and dissolved to prepare a solution, and then the resultant solution was slowly added while stirring to the solution containing the specific polymer A dissolved therein so as to disperse the photopolymerization initiator therein. The resultant liquid was heated at 60° C. for 8 hours, and methanol was removed. A quantity of water equal to the decreased weight was added. Thereafter, filtration with #420 filter cloth (pore size: 60.5 μm) was carried out, so that solids having a large dispersion size were removed to produce a composition J for forming a layer to be plated (dispersion liquid) of Comparative Example 1. At this time, the content of methanol contained in the water-alcohol mixed solvent was 5.51% by mass. Further, after the production of the composition J for forming a layer to be plated of Comparative Example 1 and subsequent leaving thereof to stand for 10 minutes, occurrence of precipitation was seen by visual observation.

A metal pattern material having a copper plated film was obtained in the same manner as Example 1 except that the composition A for forming a layer to be plated, used in Example 1, was changed to the above obtained composition J for forming a layer to be plated.

### Comparative Example 2

Preparation of Composition K for Forming a Layer to be Plated

8.9 g of water, 0.37 g of NaHCO₃, and 0.66 g of the specific polymer B (the above-described structure, solid content: 99% by mass, weight average molecular weight: 16,000) were mixed and stirred to prepare a solution containing the specific polymer B dissolved therein. Separately, 0.5 g of methanol, 0.021 g of water-insoluble photopolymerization initiator (IRGACURE 907) and 0.021 g of surfactant (Aqalon RN-20) were mixed and dissolved to prepare a solution, and then the resultant solution was slowly added while stirring to the solution containing the specific polymer B dissolved therein so as to disperse the water-insoluble photopolymerization initiator therein. The resultant liquid was heated at 60° C. for 8 hours, and methanol was removed. A quantity of water equal to the decreased weight was added. Thereafter, filtration with #420 filter cloth was carried out, so that solids having a large dispersion size were removed to produce a composition k for forming a layer to be plated (dispersion liquid) of Comparative Example 2. At this time, the content of methanol contained in the water-alcohol mixed solvent was 0% by mass. Further, after the production of the composition K for forming a layer to be plated of Comparative Example 2 and subsequent leaving thereof to stand for 10 minutes, occurrence of precipitation was seen by visual observation.

A metal pattern material having a copper plated film was obtained in the same manner as Example 1 except that the composition A for forming a layer to be plated, used in Example 1, was changed to the above obtained composition K for forming a layer to be plated.

### Comparative Example 3

Preparation of Composition L for Forming a Layer to be Plated

0.30 g (7.5% by mass) of the specific polymer A (solid content: 87% by mass) used in Example 1, 0.07 g (1.75% by mass) of sodium hydrogen carbonate, 1.63 g (40.6% by mass) of water and 2.0 g (49.9% by mass) of methanol were mixed while stirring to dissolve the specific polymer A, followed by further stirring to prepare a composition L for forming a layer to be plated of Comparative Example 3.

The same manner as Example 1 was carried out except that the composition A for forming a layer to be plated, used in Example 1, was changed to the above-obtained composition L for forming a layer to be plated.

Evaluation of Pattern-Forming Performance

The plated film produced by using each of the compositions for forming a layer to be plated, obtained in Examples 1 to 8, had a thickness of 1 μm, and a metal pattern having high resolution of mask size of ±1% or less was confirmed by observation using an optical microscope. It was confirmed that the metal pattern obtained in Example 9 is a metal pattern having high resolution of mask size of ±5% or less.

The plated films produced by using the composition for forming a layer to be plated, obtained in Comparative Examples 1 and 2, had a thickness of 1 μm. It was confirmed that the metal pattern obtained by using a photomask having line and space of 300 μm had a wiring width exhibiting a 40% to 50% increase. In the composition obtained without filtration by a filter cloth, spaces between wirings were filled in (metal pattern having a wiring width exhibiting a 100% or more increase), and formation of a pattern having high resolution was difficult.

Further, pattern formation was attempted using the composition for forming a layer to be plated, not containing the water-insoluble photopolymerization initiator obtained in Comparative Example 3, but a film was not formed.

Line and space of the pattern obtained in the above-described Examples and Comparative Examples were measured. With respect to the line width of line and space of the photomask used in pattern exposure, when a fluctuation range of the wiring width was less than 1%, it was evaluated as “O”; when a fluctuation range of the line width was from 1% to less than 5%, it was evaluated as “Δ”; and when a fluctuation range of the line width was 5% or more, it was evaluated as “X”. In this evaluation, “O” and “Δ” are levels where there are no practical problems. The results are shown in Table 1 below.

Evaluation of Adhesion

Using the composition for forming a layer to be plated, each obtained in Examples 1 to 9 and Comparative Examples 1 to 2, and carrying out exposure thereto without a photomask, the composition layer to be plated was formed on the entire surface of the substrate, and a plated film having a thickness of 18 μm was produced by whole surface electroless plating and electroplating.

With respect to the plated film thus obtained, a cross cut test (JIS-K5600) was carried out. From the result that peeling of even 1 of 100 squares was not observed, it is understood that the formed metal film has a sufficient adhesiveness to the substrate.

Evaluation of Sensitivity

In the above-described Examples and Comparative Examples, the coated film of the composition for forming a layer to be plated was cured while fixing the exposure amount at 3000 mJ, followed by development. When film formation was exhibited, it was evaluated as “O”, and when film formation was not exhibited, it was evaluated as “X”. The results are shown in Table 1 below.

Evaluation of Drying Time

In the above-described Examples and Comparative Examples, when sufficient drying was obtained at 80° C. for 5 minutes, it was evaluated as “A”; when a sufficient drying was obtained at 120° C. for 15 minutes, it was evaluated as “B”; when drying at 120° C. for 60 minutes was necessary, it was evaluated as “C”, and when drying at 120° C. for 60 minutes was insufficient, it was evaluated as “D”. The determination as to whether drying time is sufficient or insufficient was performed as follows.

In a case in which the coated film of the composition for forming a layer to be plated was dried, when the amount of a remaining solvent was 5% by weight or less with respect to the weight of the film, the drying time is determined to be sufficient. In contrast, when the amount was more than 5% by weight, the drying time was determined to be insufficient. The amount of remaining solvent was measured as follows.

A value obtained by subtracting a weight of the substrate before coating from a weight of substrate provided with a coated film thereon after drying was designated as a total weight of the solvent and the film. Further, a value obtained by subtracting a weight of the substrate before coating from a weight of the substrate after curing, developing and drying a whole surface of the film provided on the substrate was designated as a weight of the film. The amount of remaining solvent was obtained by subtracting the above-described weight of the film from the above-described total weight of the solvent and the film. The results are shown in the following Table 1.

TABLE 1

| | Pattern forming | | |
|---|---|---|---|
| | performance | Sensitivity | Drying time |
| Example 1 | ◯ | ◯ | A |
| Example 2 | ◯ | ◯ | A |
| Example 3 | ◯ | ◯ | A |
| Example 4 | ◯ | ◯ | A |
| Example 5 | ◯ | ◯ | A |
| Example 6 | ◯ | ◯ | B |
| Example 7 | ◯ | ◯ | B |
| Example 8 | ◯ | ◯ | C |
| Example 9 | Δ | ◯ | C |
| Comparative Example 1 | X | ◯ | B |
| Comparative Example 2 | X | ◯ | B |
| Comparative Example 3 | Cured film | Cured film | Cured film |
| | not formed | not formed | not formed |

From the results of Examples 1 to 9 and Comparative Examples 1 to 3, it can be seen that a pattern is formed at high sensitivity and a metal pattern having high resolution can be easily obtained in Examples using the composition for forming a layer to be plated according to the invention. Further, in comparison of Examples 1 to 7 with Examples 8 and 9, it can be seen that when a water-alcohol mixed solvent is used as the water-water-soluble flammable liquid mixed solvent, the effect of the invention is conspicuous. On the other hand, in the composition of Comparative Examples 1 and 2 in which the amount of alcohol in a water-alcohol mixed solvent was small, the water-insoluble photopolymerization initiator was not homogeneously dissolved, resolution of the formed pattern was deteriorated, and in the composition of Comparative Example 3 not containing water-insoluble photopolymerization initiator, a cured film was not formed.

All publications, patent applications, and technical standards mentioned in this specification are herein incorporated by reference to the same extent as if each individual publication, patent applications, or technical standards was specifically and individual indicated to be incorporated by reference.

What is claimed is:

1. A composition for forming a layer to be plated, the composition comprising a solution in which from 1% by mass to 20% by mass of a polymer having a functional group that forms an interaction with a plating catalyst or a precursor thereof and a radical polymerizable group, and a water-insoluble photopolymerization initiator are dissolved in a mixed solvent comprising from 20% by mass to 99% by mass of a water-soluble flammable liquid and water.

2. The composition for forming a layer to be plated according to claim 1, wherein the water-insoluble photopolymerization initiator is included in the range of from 1% by mass to 20% by mass with respect to the polymer having a functional group that forms an interaction with a plating catalyst or a precursor thereof and a radical polymerizable group.

3. The composition for forming a layer to be plated according to claim 1, wherein the water-soluble flammable liquid comprises an alcohol-based solvent.

4. The composition for forming a layer to be plated according to claim 1, wherein the water-insoluble photopolymerization initiator comprises a compound having an absorbance peak in the range of from 250 nm to 400 nm.

5. The composition for forming a layer to be plated according to claim 1, wherein, in the polymer having a functional group that forms an interaction with a plating catalyst or a precursor thereof and a radical polymerizable group, the functional group that forms an interaction with a plating catalyst or a precursor thereof comprises a non-dissociative functional group or an ionic polar group that forms an interaction with a plating catalyst or a precursor thereof.

6. The composition for forming a layer to be plated according to claim 5, wherein the non-dissociative functional group comprises an ether group, or a cyano group.

7. The composition for forming a layer to be plated according to claim 5, wherein the ionic polar group comprises a carboxylic acid group.

8. The composition for forming a layer to be plated according to claim 1, wherein the radical polymerizable group comprises an acryloyl group, a methacryloyl group, an acrylamide group, a methacrylamide group, an allyl group, a vinyl group, or a styryl group.

9. The composition for forming a layer to be plated according to claim 1, wherein the polymer having a functional group that forms an interaction with a plating catalyst or a precursor thereof and a radical polymerizable group comprises a copolymer which comprises a unit represented by the following Formula (A) and a unit represented by the following Formula (B): 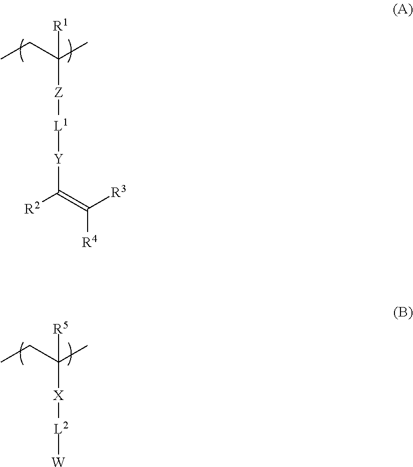
wherein, in Formula (A) and Formula (B), R¹ to R⁵ each independently represent a hydrogen atom, or a substituted or unsubstituted alkyl group; X, Y, and Z each independently represent a single bond, a substituted or unsubstituted divalent organic group, an ester group, an amide group, or an ether group; L¹ and L² each independently represent a single bond, or a substituted or unsubstituted divalent organic group; and W represents an ionic polar group that forms an interaction with a plating catalyst or a precursor thereof.

10. The composition for forming a layer to be plated according to claim 9, wherein the unit represented by Formula (B) comprises an alicyclic carboxylic group at a terminal of the unit.

11. The composition for forming a layer to be plated according to claim 9, wherein, in Formula (B), W is a carboxylic acid group, and a chain length of L² is in the range of from 6 atoms to 18 atoms.

12. The composition for forming a layer to be plated according to claim 9, wherein, in Formula (B), W is a carboxylic acid group, and both X and L² are each a single bond.

13. The composition for forming a layer to be plated according to claim 9, wherein the value of ionic polarity or an acid value of the unit represented by Formula (B) is in the range of from 1.5 mmol/g to 10.0 mmol/g.

14. The composition for forming a layer to be plated according to claim 9, wherein the polymer having a functional group that forms an interaction with a plating catalyst or a precursor thereof and a radical polymerizable group comprises a copolymer further comprising a unit represented by the following Formula (C): 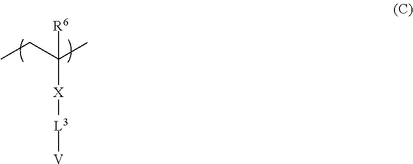
wherein, in Formula (C), R⁶ represents a hydrogen atom, or a substituted or unsubstituted alkyl group; X represents a single bond, a substituted or unsubstituted divalent organic group, an ester group, an amide group, or an ether group; L³ represents a single bond, or a substituted or unsubstituted divalent organic group; and V represents a non-dissociative functional group that forms an interaction with a plating catalyst or a precursor thereof.

15. The composition for forming a layer to be plated according to claim 1, wherein the content of the water-soluble flammable liquid in the mixed solvent is in the range of from 30% by mass to 80% by mass.

16. The composition for forming a layer to be plated according to claim 7, wherein the composition further comprises an additive selected from the group consisting of sodium hydrogen carbonate, sodium carbonate and sodium hydroxide.

17. The composition for forming a layer to be plated according to claim 1, wherein the water-insoluble photopolymerization initiator comprises a benzoin compound or a derivative thereof; a benzyl ketal-based compound or a derivative thereof; a hydroxy ketone-based compound or a derivative thereof; a benzophenone-based compound or a derivative thereof; an acetophenone-based compound or a derivative thereof; an α-aminoalkyl phenone-based compound or a derivative thereof; a bisacyl phosphinoxide-based compound or a derivative thereof; an acyl phosphinoxide-based compound or a derivative thereof; a thioxanthone-based compound or a derivatives thereof; an anthraquinone-based compound or a derivative thereof; or an oxime ester-based compound or a derivative thereof.

18. A method of producing a metal pattern material comprising:
coating the composition for forming a layer to be plated according to claim 1 on or above a substrate or an adhesion-aiding layer to form a coated film for forming a layer to be plated, and then applying energy to the coated film for forming a layer to be plated and curing the coated film at a portion to which the energy has been applied;
forming a patterned layer by developing an uncured portion of the coated film on or above the substrate or the adhesion-aiding layer with an aqueous solution;
applying a plating catalyst or a precursor thereof to the patterned layer; and
plating the plating catalyst or the precursor thereof.

19. A method of producing a metal pattern material according to claim 18, wherein the application of energy is carried out by exposure to light having a wavelength of from 250 nm to 400 nm.

20. A metal pattern material produced by the method according to claim 18.
